(19) United States
(12) Patent Application Publication
(10) Pub. No.: US 2025/0208348 A1
(43) Pub. Date: Jun. 26, 2025

(54) WAVELENGTH LOCKER INTEGRATION METHODS AND PROCESSES EXPLOITING PRINTED PHOTONIC STRUCTURES

(71) Applicant: AEPONYX INC., MONTREAL (CA)

(72) Inventors: ASSANE NDIEGUENE, GRANBY (CA); MARTIN BERARD, STE-CATHERINE-DE-LA-JACQUES-CARTIER (CA); ANDRE FEKECS, SHERBROOKE (CA); ANNABELLE GASCON, VERDUN (CA); YANNICK LAPIERRE, MONTREAL (CA); CEDRIK COIA, GREENFIELD PARK (CA); DAMIEN MICHEL, BROMONT (CA)

(21) Appl. No.: 18/848,395

(22) PCT Filed: Mar. 3, 2023
(86) PCT No.: PCT/CA2023/050274

§ 371 Date: Sep. 18, 2024

Related U.S. Application Data
(60) Provisional application No. 63/324,303, filed on Mar. 28, 2022.

(51) Int. Cl. G02B 6/136; B33Y 80/00; G02B 6/12

(52) U.S. Cl. CPC G02B 6/136; B33Y 80/00; G02B 2006/12121; G02B 2006/12123

(57) ABSTRACT

The packaging of integrated optical components for telecommunication systems is increasingly a challenge as long-haul signal transmission and detection become the dominant paradigm in data communications. This packaging can include co-packaging semiconductor-based laser diodes with silicon based photonic circuits to provide integrated wavelength locking modules where the requirements of maximizing yield for low component costs, reduced insertion losses, low packaging costs and mass production scalability are met. In order to address this methods and components to address these often conflicting requirements are presented to provide the required low loss, high yield, scalable optical interconnection between optical components. These methods and components exploit guided printed photonic structures, unguided printed photonic structures and techniques for printing such printed photonic structures.

### CROSS-REFERENCE TO RELATED APPLICATIONS

This patent application claims the benefit of priority from U.S. Provisional Patent Application 63/324,303 filed Mar. 28, 2022.

### FIELD OF THE INVENTION

invention is directed to optical components and more particularly to establishing structures and methods for the provisioning of wavelength lockers with photonic integrated components, silicon based photonic components, co-packaged photonic assemblies with silicon and semiconductor based photonic components exploiting printed photonic structures and printed photonic structure techniques.

### BACKGROUND OF THE INVENTION

The packaging of integrated optical components for telecommunication systems is increasingly a challenge as long-haul signal transmission and detection become the dominant paradigm in data communications. Transmitting optical signals over long distances implies stringent constraints to maintain signal sensitivity wherein optical interconnectivity losses at every interface, component, system, or sub-system within the optical path should be minimized. In contrast, applications such as optical interconnectivity within a datacenter require highly cost-effective communication using cost-effective and energy efficient devices which exploit low power transceivers but similarly require low loss optical interconnections. Also, the increased number of devices, such as optical switches, in the optical path contribute to those new requirements.

Against this background the ever-increasing demand for increased data rates has led to a migration from coarse wavelength division multiplexing (WDM) (CWDM) to dense WDM on grids of 200 GHz, 100 GHz, 50 GHz and even 25 GHz. Such networks employ wavelength filtered or locked optical sources, wavelength filters for routing and add-drop functionality as well as optical receivers. This has resulted in a growing need for fixed bandpass filters and tunable bandpass filters. With increasing data rates such networks are evolving from Intensity Modulation with Direct Detection (IM-DD) to coherent optical telecommunication schemes resulting in a requirement for low-cost wavelength-stabilized continuous wave (CW) integrated laser sources at either end of the optical links.

Silicon photonics is a now well established technology for densifying integrated optics systems functionalities by leveraging the economies of scale of the CMOS microelectronics industry. Generally, silicon photonics is a passive waveguide technology. Despite significant research efforts over an extended time, active silicon photonic devices that efficiently generate or absorb photons, i.e., laser diodes (LDs), light emitting diodes LEDs and photodiodes (PDs) do not exist. Generally, the current state of light emission and detection in integrated optic is reserved to low-scale III-V semiconductor materials such as indium phosphide (InP), gallium arsenide (GaAs) and alloys thereof such as InGaAsP. Monolithic design of optical circuits would still be a possibility with such material but would make the overall system expensive. Currently, none of the silicon optical sources match the performance of compound semiconductor based optical sources and the majority of research approaches do not solve how to integrate them with CMOS microelectronic circuits etc. Accordingly, the solutions to date and for the foreseeable future rely upon the hybrid integration of compound semiconductor optical sources within integrated photonic circuits that employ silicon as the substrate and/or waveguide. While heterogeneous integration is gaining considerable amounts of momentum, it remains a prohibitively costly approach to photonic integration that may only be suitable for a restricted set of high-volume consumer applications.

Accordingly, there is an interest for co-packaging semiconductor-based laser diodes with silicon based photonic circuits to provide integrated wavelength locking modules where the requirements of maximizing yield for low component costs, reduced insertion losses, low packaging costs and mass production scalability are met.

Accordingly, the inventors have established methods and components to address these often conflicting requirements to achieve the required low loss, high yield, scalable optical interconnection between a semiconductor laser diode (e.g., a distributed Bragg reflector (DBR)—externally modulated laser (EML) (DBR-EML)) and silicon photonic circuit based wavelength-locking elements. These methods and components exploiting printed photonic structures and printed photonic structure techniques.

Other aspects and features of the present invention will become apparent to those ordinarily skilled in the art upon review of the following description of specific embodiments of the invention in conjunction with the accompanying figures.

### SUMMARY OF THE INVENTION

It is an object of the present invention to mitigate limitations in the prior art relating to optical components and more particularly to establishing structures and methods for the provisioning of wavelength lockers with photonic integrated components, silicon based photonic components, co-packaged photonic assemblies with silicon and semiconductor based photonic components exploiting printed photonic structures and printed photonic structure techniques.

In accordance with an embodiment of the invention there is provided a method comprising:
providing a semiconductor laser diode (SLD) comprising:
   an optical waveguide between a first end of the SLD and a second distal end of the SLD;
providing a photonic integrated circuit (PIC) comprising:
   an input waveguide to be optically coupled to the second distal end of the SLD for receiving optical signals generated by the SLD;
   an optical spectrometer circuit having an input coupled to the input waveguide and a plurality of output waveguides; and
   a plurality of monitoring photodiodes (MPDs), each MPD of the plurality of MPDs coupled to a predetermined output waveguide of the plurality of output waveguides;
providing an optical fiber having a facet to be optically coupled to the first end of the SLD for receiving optical signals generated by the SLD;
assembling the SLD upon a first carrier;
assembling the PIC upon a second carrier;
assembling the optical fiber upon a micro-machined optical bench (MMOB);
forming a first printed photonic structure (PPS) disposed between the optical fiber and the optical waveguide of the SLD at the first end of the SLD; and
forming a second PPS disposed between the input waveguide of the PIC and the optical waveguide of the SLD at the second distal end of the SLD.

In accordance with an embodiment of the invention there is provided a method comprising:
providing a semiconductor laser diode (SLD) comprising:
an optical waveguide between a first end of the SLD and a second distal end of the SLD;
providing a photonic integrated circuit (PIC) comprising:
   an input waveguide to be optically coupled to the second distal end of the SLD for receiving optical signals generated by the SLD;
   an optical filter having an input coupled to the input waveguide and an output; and
   a monitoring photodiode (MPD) coupled to the output of the optical filter;
assembling the SLD upon a first carrier;
assembling the PIC upon a second carrier;
positioning the second carrier in a position relative to the first carrier such that second distal end of the optical waveguide and input waveguide of the PIC are disposed facing each other;
forming a first printed photonic structure (PPS) upon the second distal end of the optical waveguide;
forming a second PPS upon a facet of the PIC at the input waveguide; wherein
the first PPS and second PPS are printed in situ once the second carrier and first carrier have been positioned.

In accordance with an embodiment of the invention there is provided a method comprising:
providing an optical waveguide forming part of an optical circuit;
providing an optical element to be optically coupled to the optical waveguide;
assembling the optical circuit and optical element as part of an optical component; and
forming a printed photonic structure (PPS) to optically couple signals from the optical waveguide to a predetermined portion of the optical element.

In accordance with an embodiment of the invention there is provided a method comprising:
providing an optical waveguide forming part of an optical circuit;
providing an optical element to be optically coupled to the optical waveguide;
providing another optical element;
assembling the optical circuit and optical element as part of an optical component;
forming a first printed photonic structure (PPS) to couple optical signals from the optical waveguide to a predetermined portion of the optical element;
forming a second PPS to couple a portion of the optical signals from the first PPS to a predetermined portion of the another optical element.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 depicts a schematic of a mechanical structure for the formation of a printed photonic structure (PPS) between an optical fiber within a U-or V-groove formed within a silicon substrate and an optical waveguide formed upon the silicon substrate according to an embodiment of the invention;

FIG. 2 depicts an optical micrograph of a PPS between an optical fiber within a U-or V-groove formed within a silicon substrate and an optical waveguide formed upon the silicon substrate according to an embodiment of the invention;

FIG. 3 depicts a scanning electron micrograph of PPS interconnections between a pair of optical fibers and a pair of optical waveguides according to an embodiment of the invention;

FIG. 4 depicts a monitoring photodetector (MPD) die according to an embodiment of the invention;

FIG. 5 depicts the integration of the MPD die of FIG. 5 within a photonic integrated circuit (PIC) according to an embodiment of the invention

FIG. 6 depicts a schematic of a PIC showing the optical fiber and MPD sections according to an embodiment of the invention;

FIG. 7 depicts a schematic of a micro-machined optical bench (MMOB) and laser chip-on-carrier (CoC) assembly absent the common carrier beneath prior to the formation of a printed photonic structure (PPS) according to an embodiment of the invention;

FIG. 8 depicts an alternate integration schematic of a MMOB and laser chip-on-carrier (CoC) assembly according to an embodiment of the invention;

FIG. 9 depicts a schematic of a mechanical structure supporting the formation of a PPS between an optical fiber within a U-or V-groove formed within a silicon substrate and a facet of an optical semiconductor device mounted upon a carrier according to an embodiment of the invention whereby the semiconductor device overhangs beyond the edge of the carrier.;

FIG. 10 depicts a schematic of a common carrier upon which both implement a PIC leveraging a wavelength locker (WLL) PIC which is disposed together with a laser carrier according to an embodiment of the invention employing free-space coupling from the laser;

FIG. 11 depicts an optical micrograph of a printed photonic structure between an optical waveguide upon a PIC and a discrete semiconductor device (e.g., laser diode or semiconductor optical amplifier);

FIG. 12 depicts a schematic of a common carrier upon which both a wavelength locker (WLL) as implemented by a photonic integrated circuit (PIC) would be disposed together with a laser carrier with an optical input/output (I/O) block with an optical fiber connect the laser to the network according to an embodiment of the invention;

FIG. 13 depicts an optical micrograph of an assembled optical emitter—optical fiber assembly as depicted schematically in FIG. 11 according to an embodiment of the invention;

FIG. 14 depicts plan view schematics of two designs of micro-machined optical bench for retaining an optical fiber according to embodiments of the invention;

FIG. 15 depicts a schematic of hybrid integration of a III-V laser diode to a wavelength locker (WLL) PIC die with PPS micro-lenses on the laser diode back facet and another PPS on the WLL PIC input facet with free-space interface to the network according to an embodiment of the invention;

FIG. 16 depicts a schematic of hybrid integration of a III-V laser diode to a WLL micro-optical assembly with PPS elements to provide free space interconnect of the WLL to the laser diode according to an embodiment of the invention;

FIG. 17 depicts a schematic of hybrid integration of a III-V laser diode to a WLL die using PPS elements between the laser back facet and the WLL input facet and the laser front facet and a SiN waveguide according to an embodiment of the invention;

FIGS. 18 and 19 depict schematics of edge emitter hybrid packaging to a WLL front facet power tap integrated within the PPS interconnecting the edge emitter to an optical fiber according to an embodiment of the invention;

FIG. 20 depicts a free-space optical interconnection methodology employing PPS elements;

FIGS. 21 and 22 depict optical assemblies exploiting PPS elements to couple between elements wherein a portion of each PPS element is upon an upper surface of an optical element rather than disposed on a facet of the optical element.

### DETAILED DESCRIPTION

The present invention is directed to optical components and more particularly to establishing structures and methods for the provisioning of wavelength lockers with photonic integrated components, silicon based photonic components, co-packaged photonic assemblies with silicon and semiconductor based photonic components exploiting printed photonic structure and printed photonic structure techniques.

The ensuing description provides representative embodiment(s) only, and is not intended to limit the scope, applicability, or configuration of the disclosure. Rather, the ensuing description of the embodiment(s) will provide those skilled in the art with an enabling description for implementing an embodiment or embodiments of the invention. It being understood that various changes can be made in the function and arrangement of elements without departing from the spirit and scope as set forth in the appended claims. Accordingly, an embodiment is an example or implementation of the inventions and not the sole implementation. Various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments.

Reference in the specification to “one embodiment,” “an embodiment,” “some embodiments” or “other embodiments” means that a particular feature, structure, or characteristic described in connection with the embodiments is included in at least one embodiment, but not necessarily all embodiments, of the inventions. The phraseology and terminology employed herein is not to be construed as limiting but is for descriptive purpose only. It is to be understood that where the claims or specification refer to “a” or “an” element, such reference is not to be construed as there being only one of that element. It is to be understood that where the specification states that a component feature, structure, or characteristic “may,” “might,” “can” or “could” be included, that particular component, feature, structure, or characteristic is not required to be included.

Reference to terms such as “left,” “right,” “top,” “bottom,” “front,” and “back” are intended for use in respect to the orientation of the particular feature, structure, or element within the figures depicting embodiments of the invention. It would be evident that such directional terminology with respect to the actual use of a device has no specific meaning as the device can be employed in a multiplicity of orientations by the user or users.

Reference to terms “including,” “comprising,” “consisting” and grammatical variants thereof do not preclude the addition of one or more components, features, steps, integers, or groups thereof and that the terms are not to be construed as specifying components, features, steps, or integers. Likewise, the phrase “consisting essentially of,” and grammatical variants thereof, when used herein is not to be construed as excluding additional components, steps, features integers or groups thereof but rather that the additional features, integers, steps, components or groups thereof do not materially alter the basic and novel characteristics of the claimed composition, device or method. If the specification or claims refer to “an additional” element, that does not preclude there being more than one of the additional elements.

Within the prior art, see for example U.S. Pat. No. 8,903,205 entitled “Three-Dimensional Freeform Waveguides for Chip-Chip Connections”, optical waveguide structures (referred to a printed photonic structures or PPSs) are described which are formed from one or more materials which can be processed with a high-resolution, three-dimensional structuring technique to generate optical waveguides that can be directly optically connected or optically connected via special connecting structures from one optical waveguide (e.g. an optical fiber or integrated optical waveguide) to another optical waveguide (e.g. an optical fiber or integrated optical waveguide).

The inventors have established methods and embodiments for the optical interconnection between two optical waveguides, e.g. an optical fiber and an integrated photonic waveguide (e.g. silicon nitride photonic waveguide), an optical fiber and an edge emitting semiconductor device, an edge emitting semiconductor device (e.g. a LD, semiconductor optical amplifier (SOA)) and an integrated photonic waveguide, an integrated photonic waveguide to a semiconductor device, or an optical waveguide and a MOEMS device. Within the context of wavelength lockers these methods and embodiments relate to the optical interconnection between semiconductor-based laser diodes and photonic integrated circuits to provide integrated wavelength locking modules.

The inventors have also established methods and techniques embodiments for the optical interconnection between two optical waveguides exploiting free space interconnections by collimating the diverging beams using non-guiding photonic printed structures (unguided printed photonic structures) such as micro-lenses for example.

Within the following description, printed photonic structures (PPSs) are described and presented as being formed through, for example, ultraviolet (UV) light or two-photon absorption triggered processes within a liquid photosensitive materials to generate three-dimensional photonic structures such as waveguide core(s) and waveguide cladding(s), for example, in the instances of guiding printed photonic structures or micro-lenses for example in the instances of non-guiding printed photonic structures. The inventors referring to them as printed photonic structures as they are photonic structures printed or fabricated in-situ between optical elements. Through controlled positioning, precise dispense of a cured predetermined refractive index material and movement of the incident beam(s) of light, three-dimensional (3D) optical waveguides (waveguides) which are self-supporting can be generated. The inventors refer to these waveguides as being free-form waveguides as the geometry and/or position of the waveguide can be defined based upon factors including computer aided design (CAD), optical simulations, and the physical positions of the optical elements to which the PPS interfaces at either end.

Accordingly, the PPSs can support mode field diameter (MFD) conversion and matching position along these PPSs (interconnection links) between independent optical circuits components such as single mode or multimode optical waveguides (e.g. optical fiber waveguides referred to as optical fibers within this specification) and/or planar integrated waveguides of different material systems and designs, referred to as integrated optical waveguides or simply waveguides within this specification such as two-dimensional (2D) or planar waveguides and 3D or channel waveguides as referred to in the art.

Subsequent to placement of the two optical elements to be connected with the PPS, a PPS manufacturing system employing automated moving stages and/or positioning arms in combination with image processing and pattern recognition algorithms locates the waveguide cores, for example, of the optical elements being interconnected, and then locally prints the printed photonic structures, which function, in some instances where they are guided PPSs as an optical/photonic equivalent between waveguide cores to be interconnected as do electrical wirebonds between electrical structures to be interconnected. This process provides low-cost, low-loss optical interconnections within production-friendly embodiments that are scalable for mass-volume production.

Importantly, the integration of a printed photonic structure between waveguides provides for a defined and repeatable alignment between the waveguides such that the PPS can “absorb” mismatches arising from manufacturing tolerances which would otherwise either lead to high insertion losses or increased costs of manufacturing to achieve tighter manufacturing tolerances.

However, it would be evident to one of skill in the art that other direct write or additive manufacturing technique may be employed to generate the PPS(s) without departing from the scope of the invention. Further, whilst the light-based methodologies described and depicted exploit what the inventors refer to later in this specification as a “pool” of the light sensitive material(s) to form the waveguide core/cladding it would be evident that within other embodiments of the invention alternate deployment means for a liquid selectively cured material may be employed such as controlled micro-dispensing etc. Further, other optical or non-electrical techniques may be employed to “cure” the liquid. “Curing” may for example be through cross-linking, optically induced polymerization etc. Optionally, two or more beams may be employed to “write” the PPS wherein each beam is at an intensity insufficient to trigger the transition in the material from liquid to solid but the overlapping point of these beams has sufficient intensity to trigger the transition. Optionally, a single beam may be employed with a very shallow focal depth such that in the unfocussed regions the power density is insufficient to trigger the transition in the material from liquid to solid but the focal point has sufficient power density to trigger the transition.

Optionally, it would be evident that other direct write techniques such as additive manufacturing techniques may be employed without a “pool” of material. For example, WO/2018/145,194 entitled “Methods and Systems for Additive Manufacturing” describes techniques referred to as Selective Spatial Solidification to form a 3D piece-part directly within a selected build material whilst Selective Spatial Trapping “injects” the build material into a manufacturing system and selectively directs it to accretion points in a continuous manner.

Within the following sections exemplary PPS interconnections are described with respect to the interconnection of optical elements/optical waveguides. It would be evident to one of skill in the art that the PPS interconnection designs and methodologies as described may be applied to other optical interconnections either discretely or in combination without departing from the scope of the invention.

### A: Integrated Photonic Waveguide to Single-Mode Fiber Coupling via Printed Photonic Structure

Within this section the specific context of writing a printed photonic structure link between an optical fiber and an integrated photonics silicon nitride waveguide is described and presented in order to present the techniques for forming a printed photonic structure. However, it would be evident that in order to provide a fixed and repeatable alignment between a first optical waveguide (e.g. an optical fiber in a first instance or silicon nitride waveguide in a second instance) and a second optical waveguide (e.g. a silicon nitride waveguide in the first instance and a semiconductor waveguide in the second instance) allowing the implementation of automated printed photonic structure writing recipes essential to mass-production schemes requires that the first optical waveguide and second optical waveguide be positioned/retained in a similarly automated/mass production manner.

For example, in the instance of an optical fiber the inventors have worked to develop custom U-groove structures formed within 200 mm (8″) diameter silicon-on-insulator (SOI) wafers where the thickness of the top silicon device layer slab is engineered to make the optical fiber cores co-planar and co-axial with the silicon nitride waveguide cores to which they to be coupled thereby improving the positional alignment and reducing the misalignment that the printed photonic structure (PPS) is required to absorb. Descriptions with respect to such structures are described and depicted within WO/2020/093136 entitled “Structures and Methods for Stress and Gap Mitigation in Integrated Optical Microelectromechanical Systems” for example.

Accordingly, within embodiments of the invention, U-grooves are etched into a top silicon slab using any suitable anisotropic patterning process(es), such as Deep Reactive Ion Etching (DRIE) for instance, with a Buried Oxide (BOX) layer acting as an etch-stop to provide a repeatable etch depth. These U-grooves have their lengths, widths and depths engineered to tightly receive and host the stripped ends of optical fibers (e.g. 125 μm outer diameter single mode optical fibers such as Corning SMF-28 for example), position them to within a specified tolerance (e.g. ±1 μm in vertical and lateral directions) from the axis of the silicon nitride waveguides whilst providing sufficient space for the controlled dispense and capillary-force driven infiltration of structural (and/or optical) UV (and/or thermally) curable adhesives to fix the optical fibers within the U-grooves. A controlled dispense is engineered to provide for both thermo-mechanical stability of the fiber in the U-Groove and an optimal index contrast to enhance the fiber core detection by the vision system of the printed photonic structure writing tool. The U-Grooves lengths are also engineered to set a repeatable distance in the horizontal direction between the end facet of the optical fiber and the opposing silicon nitride waveguide.

However, the optical fibers may be fixed into position with other mechanisms such as metallized fiber/solder to metallization on the silicon substate or optical waveguide stack, attachment of a top-cover over the U-grooves and optical fibers etc.

Within embodiments of the invention as depicted and described below, the interface region between the U-groove structure(s) and the optical waveguide(s) comprises customized receptacles (referred to as a pool by the inventors) such that this pool can be filled with one or more materials from which the PPS is formed. These pools are located between the optical fibers and the silicon nitride waveguides and are meant to receive and contain, for example, a liquid photoresist from which the printed photonic structure core is written with a two-photon absorption phenomenon from an IR laser. The dimensions of the pools provide for line-of-sight visual access and waveguide detection by the PPS manufacturing system to the cores of the optical fiber and silicon nitride waveguide so that the vision system of the PPS writing tool can locate them, precisely align the tool and lock onto them. The dimensions of the pools provide for repeatable, sufficient, yet minimal volume of the photoresist to be dispensed and maintained in location to ensure a repeatable PPS writing process.

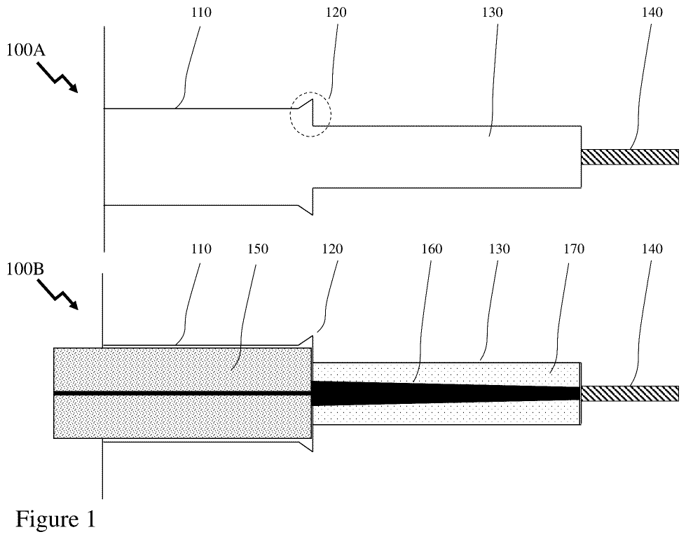

Referring to FIG. 1 there are depicted first and second Views 100A and 100B of an exemplary “pool” based PPS structure at an initial photonic integrated circuit (PIC) manufacturing stage and after assembly with optical fiber and formation of the PPS respectively according to an embodiment of the invention. Accordingly, referring to first View 100A the optical interface portion of the PIC relating to U-groove/optical fiber/PPS is depicted showing the Optical Waveguide 140 of the PIC, the U-Groove 110 (or V-Groove or other structure to locate and retain an optical fiber), and the Pool 130 within which the liquid from which the PPS will be formed.

The Pool 130 is narrower than the U-Groove 110 such that a Butt Stop 120 is formed which enables for provisioning of a fixed and repeatable separation between the end facet of the optical fiber when inserted and the facet of the Optical Waveguide 140. The sidewalls of the Pool 130 have engineered sizes and shapes to allow for adequate line-of-sight visual access for the vision system to the optical fiber core whilst improving the control over the optical and/or structural liquid dispense by acting as mechanical and capillary stoppers. An exemplary embodiment of the invention being depicted in FIG. 1B.

The Butt Stops 120 as depicted are further patterned with, optional, structures which the inventors refer to as “butterfly structures” which prevent the rounded bottom wall shapes typical of anisotropic patterning processes like DRIE, for example when forming a U-Groove, which would otherwise impede proper core-core alignment between waveguides and optical fibers by causing the latter to lift as they are butted against the Butt Stop 120 (U-groove-to-pool separation sidewall).

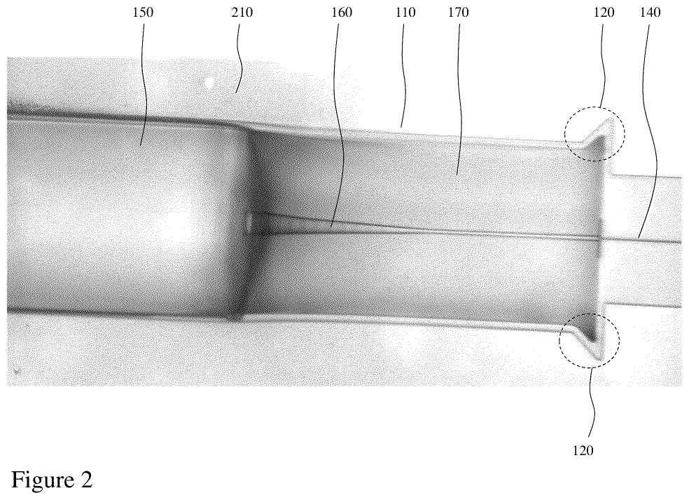

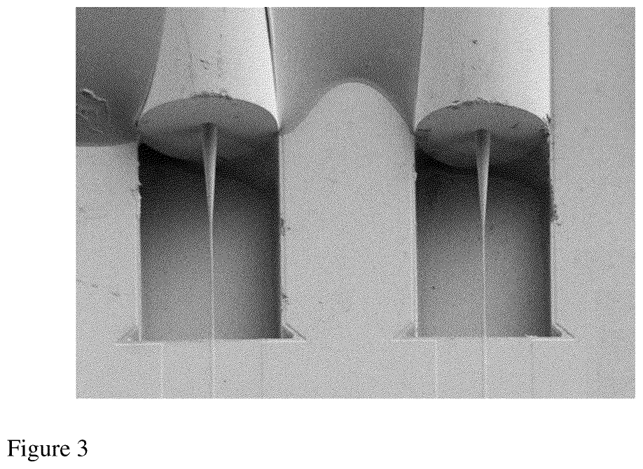

Subsequently, as depicted in second View 100B, the Optical Fiber 150 is inserted such that the end facet of the Optical Fiber 150 forms the fourth and initially missing wall of the pool for the liquid with the Pool 130. Accordingly, a Pool 130 can be embodied by backing up the Optical Fiber 150 in the U-Groove 110 (or V-groove) as depicted in FIGS. 2 and 3, respectively. In this manner the liquid is dispensed into a region with sidewalls limited its flow where the properties of the liquid are such that capillary wicking of the liquid out into the U-Groove 110 is limited or avoided. However, in other instances, this wicking of the liquid may be employed to provide a curable adhesive layer between the silicon (or other material) substrate within which the U-Groove 120 is formed and the Optical Fiber 150. Optionally, the Optical Fiber 150 may be fixed into position within the U-Groove 110 prior to the formation of the PPS 160 between the end facet of the Optical Fiber 150 and the facet of the Optical Waveguide 140 or within other embodiments of the invention an overall curing of another material, Filler 170, employed to provide a cladding of the PPS 160.

Accordingly, the U-groove-pool-waveguide structure are implemented through a microfabrication process exploiting process and/or design building blocks/elements from a proprietary MEMS fabrication process of one applicant, see for example WO/2020/093136 entitled “Structures and Methods for Stress and Gap Mitigation in Integrated Optical Microelectromechanical Systems.” Accordingly, the U-Groove-Pool and U-Groove-Pool-Waveguide alignments are established by design and are hardcoded onto microfabrication photomasks thereby established repeatability of lateral and longitudinal geometry aspects whilst those vertical to the plane of the U-Groove-Pool-Waveguide are established through the design of the optical waveguide stack, underlying stack elements (e.g. BOX), silicon wafer etc. and processing tolerances and/or integration of etch stops etc.

An optical micrograph of a variant design of a PPS between an optical fiber within a U-or V-groove formed within a silicon substrate and an optical waveguide formed upon the silicon substrate according to an embodiment of the invention is depicted in FIG. 2. FIG. 2 depicts the final assembled interface wherein the Silicon Substrate (Si-Substrate) 210, U-Groove 110, Optical Fiber 150, and Optical Waveguide 140 are shown. Also depicted are PPS 160 between the end facet of the Optical Fiber 150 and the facet of the Optical Waveguide 140 and Filler 170. Within other embodiments of the invention Filler 170 may be omitted. The region between the end face of the Optical Fiber 150 and the U-Groove 110 to the facet with the Optical Waveguide 140 forms a pool. However, in contrast to FIG. 1 the Butt Stops 120 are now at the facet of the etched Si-Substrate 210 where the Optical Waveguide 140 terminates. As noted above these Butt Stops 120 or butterfly structures prevent obstruction that may be otherwise caused by the rounded (in the instance of a U-Groove) bottom wall shapes typical of anisotropic patterning processes like DRIE employed in the manufacturing process. In this instance, whilst the Butt Stops 120 are not engaged against the end of the Optical Fiber 150 they ensure a vertical facet which would otherwise impede on proper core-core alignment between the Optical Waveguide 140 and PPS 160.

Now referring to FIG. 3 there is depicted an optical micrograph of a pair of optical fibers which are optically coupled to a pair of optical waveguides via a pair of UWBs. In contrast, to the optical micrograph in FIG. 2 it is evident that the Filler 170 has not been placed into the pool formed by the sidewalls of the U-groove, end facet of the silicon and the end fact of the optical fiber. Accordingly, FIG. 3 may, within some embodiments of the invention depict the scenario where the PPS is air-clad such that no Filler 170 is employed. Optionally, within other embodiments of the invention the PPS may be a core-clad structure without employing a Filler 170 as mechanical element. Optionally, within other embodiments of the invention FIG. 3 depicts the fabrication partly completed prior to the deposition and curing of the Filler 170 within the pool.

### B: Silicon Nitride Waveguides

Within exemplary embodiments of the invention the optical waveguides, e.g., Optical Waveguide 140 in FIG. 1, employed for the PICs and therein coupling to and/or from other optical elements with PPSs are based upon a 450 nm thick Silicon Nitride (SiₓN_{y}, referred to subsequently as SiN for ease of reference) core symmetrically clad with 3.2 μm of Silicon Oxide (SiO₂) above and below. This material choice provides an advantage over waveguides with silicon cores in regard of PPSs because the lower core-clad refractive index contrast results in larger mode field diameters (MFD) than silicon waveguides. Larger MFDs allow for more overlap in the interconnection region, which results in increased tolerances with respect to misalignment between the PPS and the SiN cores to achieve low-loss optical links.

Within embodiments of the invention the SiN waveguide cores are patterned with tapers in the region close to the interface with the PPS core in order to increase the MFD further, thereby providing an additional relaxation of the core-to-core alignment constraints and tolerances. The relatively larger PPS cores provide improved scalability of the technology towards shorter wavelengths, making the technology applicable to PIC devices operating in different wavelength ranges including the L, C, S, E and O-bands of the infrared telecommunications spectrum, namely 1565 nm-1625 nm, 1530-1565 nm, 1460-1530 nm, 1360-1460 n and 1260 nm-1360 nm respectively.

Within embodiments of the invention the SiN waveguide cores are patterned with square cross-section tapers in the region closest to the interface with the PPS core in order to provide mode fields with angular symmetry such that when coupled with printed photonic structure cores with cylindrical symmetry, optical interfaces with low polarization sensitivity are produced.

Within embodiments of the invention, the SiN waveguides between the PPS interfaces and the PIC/MOEMS etc. elements are implemented with low coupling efficiency (i.e., 1%) evanescent couplers to provide power taps located close to the PPS optical interface. These are typically implemented within the non-tapered section of the SiN waveguides. The output from these power taps are coupled to surface grating couplers, monolithically integrated photodiodes, or other optical means for in-line monitoring of the quality and insertion losses of the PPS interfaces. Accordingly, once the PPS core has been formed then the optical performance of the PPS interface can be established prior to the PPS cladding material being dispensed and cured. This provides an opportunity within the workflow for a rework step before the cladding is implemented providing a non-reworkable PPS or a PPS with increased complexity/difficulty of removal. Such a re-work stage is implemented as a way to improve the yield of assembly processes whereby costly parts are mated through PPS to make up systems or sub-systems.

### C: Wavelength Locker Block

A wavelength locker (WLL) is a small optical sub-system (or block) that provides a stable optical frequency reference to improve the long-term frequency stability of a singlemode lasers, i.e., it locks the wavelength of the laser to the wavelength defined by the reference element which may be fixed or tunable through external electronic/transduction/firmware methods. The optical frequency reference and the singlemode laser may in some instances be designed to operate upon a single wavelength channel on a defined grid (e.g., 200 GHz, 100 GHz, 50 GHz, or 25 GHz for example) within a given telecommunications band (e.g., L-band, C-band, S-band, E-band, or O-band for example). The optical frequency reference and the singlemode laser may in some instances be designed to operate upon multiple channels on a defined grid within a single telecommunications band or across portion of adjacent telecommunication bands.

The WLL allows for the tracking and continuous adjustment and/or compensation of the wavelength of the laser either when initially configured, re-tuned, or as it ages and drifts across its lifespan. Within the context of embodiments of the invention, the WLL block will be described as being common to all the embodiments disclosed. However, it would be evident that within other embodiments of the invention that the WLL block may be specific to a specific application, specific semiconductor laser design, etc. A WLL block as employed within embodiments of the invention comprises an photonic integrated circuit (PIC) comprising at least two sections, a first section comprising an optical spectrometric filter stage, and a second section comprising an optical-to-electrical conversion stage. This PIC can be a standalone element or it can be a subsection of a larger monolithic PIC.

### C1: Optical Spectrometric Filter Stage

The spectrometric filter stage contains an unfiltered output port (usually one) used as a power reference and one or more onboard demultiplexing filters coupled to a number of output ports which are each routed to and optically connected to an optical-to-electrical conversion stage (photodetector) of a number of photodetectors. Within embodiments of the invention, the demultiplexing filter(s) may be a free space micro optics element or a PIC that comprises one or more of Mach-Zehnder Interferometer(s) (MZI), Fabry-Perot resonator(s) (FP), micro ring resonator(s) (MRR), ring-assisted MZIs, arrayed waveguide grating (AWG), diffraction grating, Echelle grating, mono-order grating (MOG), Bragg grating or any other type of demultiplexing filter based on waveguides.

Within the following description of embodiments of the invention, the optical waveguides exploit SiO₂-Si₃N₄-SiO₂ waveguides comprising a silicon nitride (Si₃N₄) core with upper and lower silicon dioxide (SiO₂) cladding although it would be evident that within other embodiments of the invention other silicon-on-insulator (SOI) waveguides may be employed as well as other silicon based optical waveguides. However, within other embodiments of the invention other waveguide technologies may be employed without departing from the scope of the invention.

The output ports are spectrally separated by an amount (m×FSR)/n, where FSR is the Free Spectral Range of the filter, and m, n are integer numbers determined from the desired tuning resolution. The FSR of the filters can be equal to, for example, the channel separation of a tunable laser employed within a tunable optical coherent receiver or in Next-Generation Passive Optical Network 2 (NG-PON2, also known as time-and wavelength-division multiplexing (TWDM)) tunable transmitters. Alternatively, the FSR can be any other suitable value, like a fraction or a multiple of a channel separation, or some fraction of the central desired frequency in the case of non-tunable fixed wavelength lasers. Some of these filtered output ports can be spectrally complementary.

Within some instances the demultiplexing filters may be thermally tuned and stabilized, such as for example described by the inventors within U.S. Provisional Patent Application 63/276,052 entitled “Structures and Methods for Phase Shifting in Optical Devices”, or untuned. Within other embodiments of the invention the demultiplexing filters may be electro-optically tuned if the waveguide technology supports an electro-optic effect or current injection for example.

In the case of tuned filters, single instances of filters may be used with their output ports transmission peaks designed to fit with the central wavelength of the lasers' channels. In such cases the closed feedback loops will work to maintain the lasers bias through performing either one of i) maximizing the photocurrent collected at optical-to-electrical conversion stage, ii) minimizing an error signal (ratio or differences), or iii) match a linear combination of elements in a look-up table. The same control logic may apply to any other point selected along the filter transmission spectrum from which the closed feedback loop circuit may maintain the corresponding photocurrent at a local maximum.

In the case of non-thermally tuned filters, the WLL may exploit a combination of two or more filters with suitably determined crossing points between their transmission spectra for continuous tracking of laser alignment through the photocurrents collected at the output ports of the two or more filters.

### C2: Optical-to-Electrical Conversion

The optical-to-electrical conversion stage comprises of one or more photodiodes (PDs) each monitoring an output of the spectrometer filter stage (hereinafter referred to as a monitoring PD or MPD) that each convert the optical signals from an output port of the spectrometer filter stage to an electrical photocurrent. Accordingly, the MPDs yield electrical signals generated in dependence upon optical signals are employed in electronic feedback control loops which may be employed to control one or more different aspects of the wavelength locked optical source including, for example, AC and/or voltages and/or currents applied to the electrodes the semiconductor laser chip (die) may have (such as gain medium, optical mirror etc.) and tuning elements of the spectrometer filter stage (e.g. tuning electrodes of discrete filter elements, the PIC overall etc.). These feedback control loops allowing these signals to be continuously adjusted so as to lock the wavelength(s)/frequency(ies) of the optical source either over time to a single channel or in adjusting the operating channel of the optical source. In some embodiments the power reference could be internal to the laser PIC, tuning of the laser may be implemented through control of temperature, gain current, phase of distributed mirror. Tuning of the spectrometer may include optical length or phase variations.

Within the embodiment of the invention described and depicted below the MPDs, which are designed for side-illumination, are hybrid integrated inside cavities formed within the PIC which is formed upon a SOI wafer. These cavities are defined by a combination of dielectric and deep silicon etching in areas where silicon nitride waveguides are running such that the sidewalls intercept and reveal the waveguide core facets. The cavity depth is engineered such that the height of the side illuminated MPDs active areas is coincident with the position of the waveguide exposed core facet. The thickness of the silicon-on-insulator (SOI) wafer slab is chosen to correspond to this depth such that the buried oxide (BOX) layer serves as an etch stop providing repeatable cavity size and flat bottom. In other embodiments the MPDs could be directly and monolithically integrated to the silicon substrate in the form of, for instance, epitaxially grown SiGe PDs.

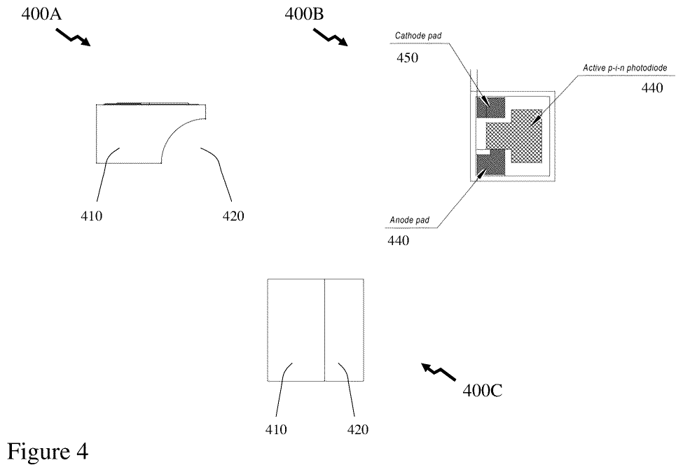

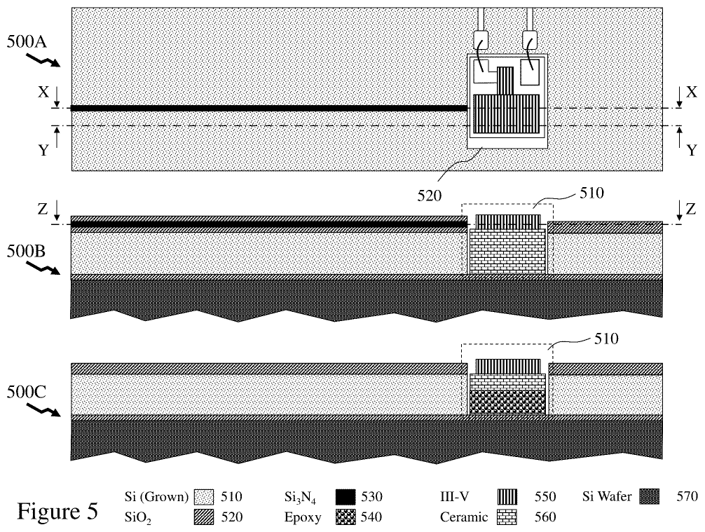

This is depicted within FIGS. 4 and 5 wherein FIG. 4 depicts an MPD die as employed according to embodiments of the invention whilst FIG. 5 depicts the integration of the MPD die within the PIC. Referring to FIG. 4 there are depicted first to third images 400A to 400C respectively of the MPD die as employed within embodiments of the invention representing a front elevation, plan elevation, and bottom elevation, respectively. As depicted the MPD die comprises an active p-i-n (PIN) photodiode (PIN PD 440) (formed from a semiconductor stack having-doped, intrinsic and n-doped layers) disposed upon a Carrier 410 where the PIN PD 440 is coupled to electrical contacts, namely Anode Pad 440 and Cathode Pad 450, which are then electrically connected to pads upon the PIC to feed the electrical signal from the MPD to the closed loop control circuit (either external to the PIC or formed within CMOS integrated within the PIC). Formed within the lower surface of the Carrier 410 is a Recess 420.

Referring to FIG. 5 there is depicted Plan 500A together with first and second Cross-Sections 500B and 500C respectively along Sections X-X and Y-Y, respectively. Plan 500A being along Section Z-Z within first Cross-Section 500B. Accordingly, the MPD 510 is depicted inserted into a Cavity 520 formed within the device stack formed atop the BOX (SiO2 520) formed upon the Si Wafer 570. Accordingly, the Cavity 520 is etched into the Si 510, SiO2 520, and Si3N4 530 deposited, using a chemical vapor process, atop the BOX. The MPD 510 is attached via Epoxy 540 within the recess in the lower surface of the MPD Carrier formed from Ceramic 560 upon which are formed the electrical contacts (Anode Pad 440 and Cathode Pad 450) together with the PIN PD formed from the III-V 550.

Within other embodiments of the invention according to the design of the MPD Carrier and the structure grown on the Si Wafer 570 the cavity may be formed by etching to a shallower depth than the BOX.

Within other embodiments of the invention the MPD may be implemented without formation of a cavity by forming a surface grating coupler in a waveguide to couple light out of the plane of the optical circuit wherein an MPD is disposed inverted above the optical circuit such that the active semiconductor layer of the MPD faces the surface grating coupler.

Within other embodiments of the invention the MPD may be implemented by forming a mirror within a waveguide, e.g., by etching the waveguide with or without additional coatings upon the formed waveguide facet to couple light out of the plane of the optical circuit wherein an MPD is disposed inverted above the optical circuit such that the active semiconductor layer of the MPD faces the waveguide facet.

An assembly process for the PIC and MPD employs the MPDs being inserted into the cavities within the upper surface of the PIC. This may be with pick-and-place tools can be active or passive and is engineered to optimize the optical to the waveguide facets. The attachment of the MPDs is made using an epoxy which may be conductive, non-conductive, ultraviolet (UV) curable, thermally curable etc. Other attachment techniques may be employed but with increased complexity. The design of the MPD Carrier is such that its thickness aligns the PIN PD with the Si3N4 core of the optical waveguide(s) it is intended to be provide an electrical signal for. As depicted in FIG. 5 the MPD 510 is coupled to a single optical waveguide. The Ceramic 560 of the MPD 510 directly abutting the BOX of the PIC wherein the Epoxy 540 is employed within the Recess 420 of the Carrier 410 and around portions of the periphery of the MPD 510 within the Cavity 520. Electrical connectivity to the MPD 510 is achieved by wire bonding the Anode Pad 440 and Cathode Pads 450 to the electrical pads formed upon the surface of the PIC which are then routed to CMOS electronics within the PIC or to contacts for connection to external electronics.

### D: Integration of Distributed Bragg Reflector Lasers With Wavelength Locker

Within the following description embodiments of the invention are directed to the integration of Wavelength Lockers (WLLs) with Externally Modulated (EM) Distributed Bragg Reflector Lasers (DBR) (EM-DBR or EML). However, the techniques may also be applied to directly modulator DBR lasers (DM-DBRs) or laser employing other wavelength selective elements providing wavelength filtering within the overall resonant cavity of the laser. A semiconductor laser diode employs a semiconductor optical gain element disposed between a pair of mirrors, one high reflectivity and one lower reflectivity to allow optical emission from the cavity, where the optical wavelength is determined by the optical properties of the cavity. A simple pair of mirrors provides a Fabry-Perot (FP) laser whilst a DBR employs distributed Bragg Grating (DBG) mirrors which results in a narrower linewidth laser. Rather than amplitude modulating the optical gain region of the DBR an EM-DBR employs an external optical modulator (on-chip or off-chip), such as a semiconductor electro-absorption (EA) modulator or a lithium niobate based electro-optic MZI, to modulate the output of the laser reducing the thermally induced optical chirp and therein optical dispersion over a long-haul telecommunications link. If the reflectivity of the high reflectivity mirror is reduced then whilst the threshold of the laser is increased, the optical signal emitting from the other “facet” of the EM-DBR can be employed for coupling into the PIC and therein the wavelength locking chip or section of the embodiment. This avoids the requirement to insert an optical tap within the modulated output of the laser or the optical cavity of the DBR.

If the DBGs are fixed then the output wavelength of the DBR is fixed whereas if the DBGs are thermally/electro-optically tuned or one/both replaced with tunable wavelength filters then the DBR can be tuned across a number of channels. Whilst consideration is primarily given within the description to DBRs tunable to a regular grid it would be evident that within other embodiments of the invention tuning to non-regular grid or specific discontinuous wavelengths may also be implemented without departing from the scope of the invention. It would also be evident that the same approach can be applied to other laser types such as DFBs.

Within the following description three types of embodiments of the invention are presented whereby:
within a first type the laser is co-integrated on the same photonic integrated circuit as implementing the WLL block;
within a second type the laser is integrated on its own metallized ceramic carrier, which is then co-packaged with the integrated photonics chip implemented WLL block on a common second ceramic carrier; and
within a third type the laser is integrated on its own two-tier metallized ceramic carrier on which the integrated photonics chip implemented WLL block is then co-integrated.

A common feature between all these embodiments is the employment of printed photonic structure (PPS) to provide the required optical connectivity between elements of the optical source, such as between the output of the laser and the optical fiber with which it is coupled to the optical network and/or between the other output of the laser and the input port of the photonic integrated circuit implemented WLL block comprising the spectrometric filter stage. PPS allow to achieve this coupling with low loss, without the necessity of resorting to costly active alignment of optical components.

### D1: Direct On-Chip Co-Integration of the Laser and the WLL

Within this embodiment of the invention, the photonic integrated circuit (PIC) bearing the spectrometric filter(s) and the MPD(s) incorporates an additional cavity aimed at receiving the bare laser chip. Within this custom micro-machined silicon hybrid integration platform therefore are six different structures:
(1): U-Grooves to host the incoming fiber for optical I/O to the laser;
(2): A first set of receptacle cavities (PPS pools) such as described above in respect of FIGS. 1 to 3 and within U.S. Provisional Patent Application 63/268,447 and World Intellectual Property Organization Patent Application PCT/CA2023/050228;
(3): A deep cavity to host and align the laser (laser cavity);
(4): A second set of receptacle cavities to serve as other PPS pools for the PPS material in the region between the laser and the silicon nitride waveguides;
(5): The silicon nitride waveguides and spectrometric filter section (within a PIC); and
(6): Another set of cavities to receive the MPDs.

These six structures are fabricated through a dual etch depth process comprising:
a first etching processes whereby the U-Grooves, the two sets of PPS pools and the MPD cavities are formed and share the same etch depth; and
a second etching process to etch further the cavity for the laser which reaches a different depth.

The combination of these two successive etches is made possible by the SOI wafers, whereby the first etch stops on the buried oxide (BOX). In other embodiments of the invention, a cavity-SOI with pre-defined cavities appropriately located in the handle part of the wafer may be employed so as to remove the requirement for a second etching process.

The structures of the WLL block and the MPDs) are common to all the embodiments and were described above.

A seventh structure or structures consists of the printed photonic structure (PPS) waveguides to achieve the optical link between structures (1) (U-grooves) and (3) (laser cavity) as well as between structures (3) (laser cavity) and (5) (WLL block) through structures (2) and (4) (PPS pools) respectively.

### D1A: U-Grooves

The silicon hybrid integration platform within an embodiment of the invention is based upon 200 mm silicon-on-insulator (SOI) wafers whereby the thickness of the top silicon slab is engineered to make the optical fiber cores co-planar and co-axial with the silicon nitride waveguide cores to which they are matched. The U-grooves are etched into the top silicon slab using any suitable anisotropic patterning process, such as Deep Reactive Ion Etching (DRIE) for instance, with the Buried Oxide (BOX) acting as an etch-stop guaranteeing repeatable etch depths for a fiber mechanical stop. The U-grooves have lengths, widths and depths engineered to tightly receive and host stripped ends of optical fibers. Width and depth are adjusted to position optical fibers to within 35 0.35 μm in y, z from the axis of the silicon nitride waveguides to cope with the fiber fabrication tolerance specification. According to the design requirements the U-grooves may be designed to match the upper limit variation of standard 125 μm outer diameter optical fiber or a reduced diameter optical fiber such as 80 μm diameter for example. They can also be engineered to introduce a controlled vertical offset, e.g., of a few tens of μm, to improve yield repeatability and efficiency. In other embodiments, V-Grooves may be employed removing the requirement for SOI wafers.

This design leaves enough space for the controlled dispense and capillary-force driven infiltration of structural (and/or optical) UV (and/or thermally) curable adhesives such as described and depicted with respect to FIGS. 1 and 2. The controlled dispense is engineered for maximum infiltration coverage to provide for both thermo-mechanical stability of the fiber in the U-Groove and an optimal index contrast to enhance the fiber core detection by the vision system of the printed photonic structure writing tool. The U-Grooves length are also engineered to set a repeatable distance in the light propagation axis (x) between the optical fiber cores and the opposing silicon nitride waveguide cores. The U-groove ends can be further patterned with butterfly structures that eliminate rounded bottom wall shapes typical of anisotropic patterning processes like DRIE, which would otherwise impede on proper core-core alignment between waveguides and optical fibers by causing the latter to lift as they are butted against the U-groove-to-pool separation sidewall. Although the PPS is able to absorb such misalignment, insertion losses are reduced when the z-offset between the two waveguides to be mated is below 30-50 μm.

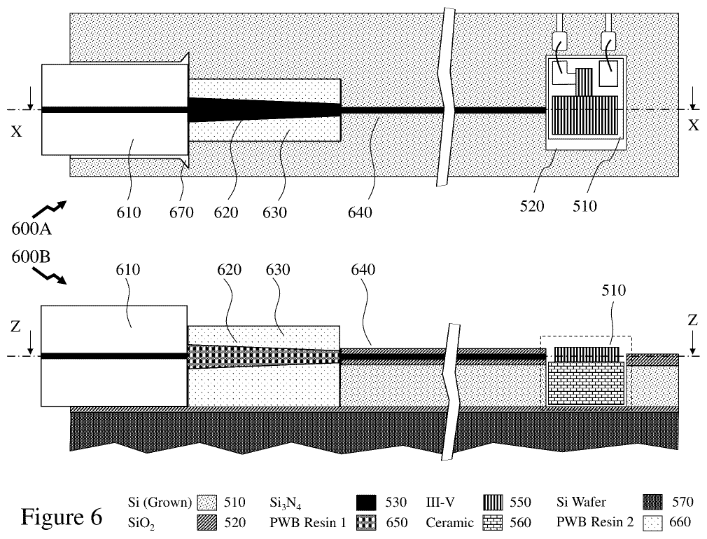

FIG. 6 depicts a Plan 600A along section Z-Z and Cross-Section 600B along section X-X of a PIC showing the optical fiber and MPD sections omitting the intervening optical spectrometer stage for clarity. Accordingly, the MPD 510 is depicted as it was in FIG. 5 on the right-hand side. On the left-hand side is the Optical Fiber 610 disposed within the U-Groove 670 wherein a PPS has been formed between the Optical Fiber 610 and Optical Waveguide 640 comprising a PPS Core 620 formed from PPS Resin 1 650 and PPS Cladding 630 formed from PPS Resin 2 660. Optionally, the PPS may be formed solely from PPS Resin 1 650 if it is air clad.

### D1B: First Set of Pools

The first set of custom-sized receptacles (referred to by the inventors as pools which hold the “pool” of material from which the PPS is formed) is located between the optical fibers and the laser. These pools receive and contain the first material, e.g., PPS Resin 1 650 which may be a liquid photoresist for example, within which the printed photonic structure cores are to be written between the optical fiber and the facet of the laser diode and subsequently encapsulated within another material, e.g., PPS Resin 2 660.

The size of the pools allows for line-of-sight visual access to the cores of the optical fiber and of the laser waveguide so that the vision system of the PPS writing tool can locate and lock onto them. The size of the first set of pools also allows to adapt the viscosity and the capillarity forces for repeatable, sufficient, yet minimal volume of photoresist to be dispensed and maintained in location to ensure a repeatable PPS printing process. The pool design allows for easy removal of the photoresist at the develop stage. The first set of pools are separated from the U-grooves by sidewalls acting as butting stops enabling fixed and repeatable distances between optical fibers and waveguide cores that also account for fiber size tolerances. The sidewalls have engineered sizes and shapes to allow for adequate line-of-sight visual access for the vision system to the optical fiber core while improving the control over the optical and/or structural adhesive dispense by acting as mechanical and capillary stoppers. The side of the pools facing the laser is open ended such that PPS material may spill into the laser cavity, however the dead volume of the latter is engineered to be minimal to avoid superfluous material consumption.

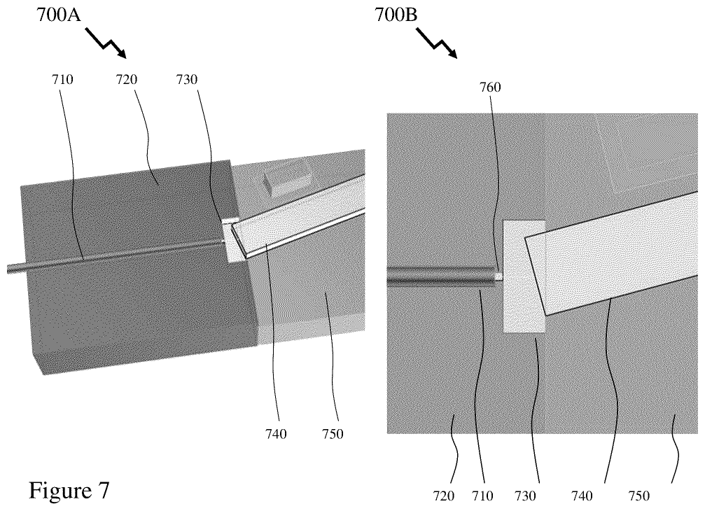

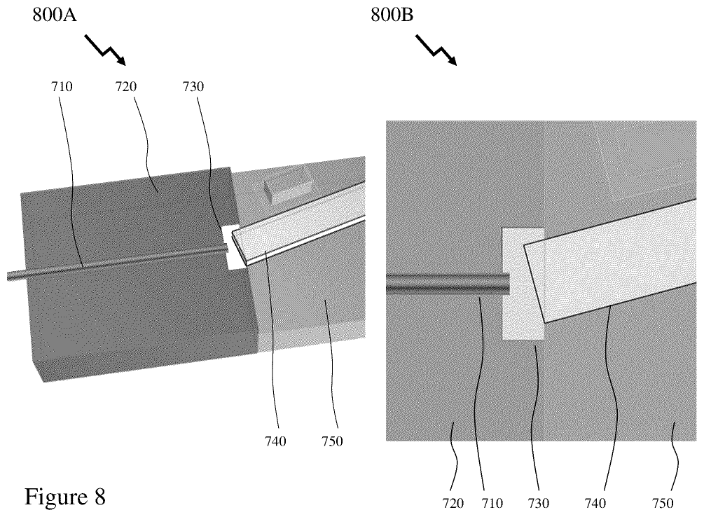

Referring to FIGS. 7 and 8 there are depicted exemplary conceptualizations for the optical fiber-laser interface prior to the formation of the PPS. Referring to FIG. 7 there is depicted a schematic of a micro-machined optical bench (MMOB) 720 and laser chip-on-carrier (CoC) 750 assembly absent the common carrier beneath prior to the formation of the PPS. For example, referring to first Image 700A the optical axis of the Optical Fiber 710 within the U-Groove (not identified for clarity) on the MMOB 720 is aligned with the optical axis of the optical waveguide upon the Edge Coupled Semiconductor Die (EC-SD) 740, e.g., a semiconductor DBR laser die or InP PIC, which is mounted to the CoC 750. However, the PPS interconnection relaxes this requirement as misalignments in the optical axes can be absorbed within the PPS interconnection. The end of the MMOB 720 having a Pool 730 for containing the liquid for forming the PPS to interconnect the Optical Fiber 710 to the EC-SD 740. The CoC 750 and MMOB 720 being mounted to a common carrier (not depicted for clarity). This interface region between the CoC 750 and MMOB 720 forming the Pool 730 is depicted in more detail in second Image 700B in FIG. 7.

The special shape of the End 760 (edge) of the U-Groove, a short region of reduced width relative to the U-groove provides for placement of the Optical Fiber 710 by butting the facet of the Optical Fiber 710 to the End 760 with a predetermined displacement, preferably below 30-50 μm, from the edge of the Pool 730 therein provided well defined positioning of the Optical Fiber 710 core. Within FIG. 7 the EC-SD 740 is depicted with its facet overhanging the edge of the CoC 740 such that the facet of the EC-SD 740 projects into the Pool 730.

As discussed above the U-Groove enables a structural glue dispense under and on the side of the Optical Fiber 710 to the U-Groove for attaching the Optical Fiber 710 to the MMOB 720. Features, such as Butt Stop 120 in FIG. 1, on the edge of the U-Groove combined with appropriate structural glue dispense enables a self-contained pool for the liquid used in the PPS, which enables low consumption of chemicals and very stable conditions for the PPS writing. Moreover, as the objective of the lithography optics is moved in axial direction during the writing step, the pool prevents excess movement of the resist which could potentially disturb the writing process.

Within another embodiment of the invention the MMOB 720 and CoC 750 are the same carrier wherein either the design of the U-Groove is modified in order to raise the core of the Optical Fiber 710 into axial alignment with the waveguide of the EC-SD 740 or the region upon which the EC-SD 740 is assembled is etched to lower the EC-SD 740 relative to the CoC 750. The integration of the fiber directly into the U-groove of the chip allows for a leveled surface with no parts higher than the working distance of the lithography system forming the PPS.

A micro-machined optical bench (MMOB) may within an embodiment of the invention be formed in silicon which is etched with one or more wet or dry etching processes to form the required micro-machined structures within the MMOB. Within other embodiments of the invention the MMOB may be formed from other materials such as a polymer or polymers, a ceramic or ceramics, a glass or glasses, a metal or metals, an alloy or alloys for example. Manufacturing processes may be co-fired green sheet based for a ceramic based MMOB or based upon Lithographie, Galvanoformung, Abformung (LIGA, lithography, electroplating, and molding) process directly or molded/stamped using a template formed by such techniques for other materials.

Referring to FIG. 8 there is depicted a schematic of a variant of the design methodology depicted in FIG. 7. Accordingly, within first Image 800A and second Image 800B the same configuration of micro-machined optical bench (MMOB) 720 and laser chip-on-carrier (CoC) 750 assembly absent the common carrier beneath prior to the formation of the PPS are depicted together with the Optical Fiber 710, Pool 730, and EC-SD 740. However, in contrast to FIG. 7, the U-Groove is now absent a structured end, e.g., the End 760 as depicted in FIG. 7, such that the end of the Optical Fiber 710 now projects into the Pool 730. Whilst this provides increased access to the facet of the Optical Fiber 710 it does not result in reduced or improved positional accuracy in that facet and accordingly the implementation of the PPS between the Optical Fiber 710 and EC-SD 740 may be subject to increased variation between devices or between elements of the same device if multiple optical elements were upon the device being packaged as a single component. This embodiment however demonstrates the backwards compatibility of an optical coupling with PPS to an already existing integration using, for instance, discreet optical elements for optical coupling.

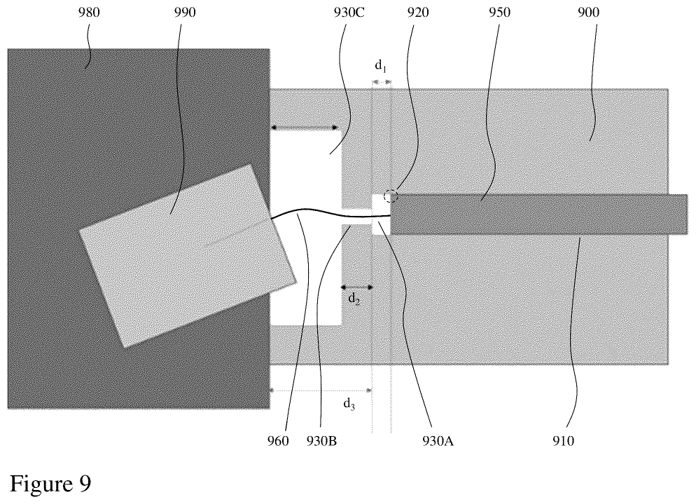

Referring to FIG. 9 there is depicted a schematic of a mechanical structure supporting the formation of a printed photonic structure (PPS) between an optical fiber within a U-or V-groove formed within a silicon substrate and a facet of an optical semiconductor device mounted formed upon a carrier according to an embodiment of the invention. FIG. 9 depicting a variant design of the pools to that depicted in FIG. 7. Accordingly, as depicted an Optical Fiber 950 is mounted within a U-Groove 910 (or a V-groove or other recess having a defined cross-section) formed within a MMOB 900 (e.g., silicon). The Optical Fiber 950 abuts an end of the U-Groove 910 where the pool begins, this being defined by a first Pool Section 930A which begins where the interface between the U-Groove 910 and first Pool Section 930A comprises Butt-Stops 920 as described above in respect of FIG. 1 which may or may not comprise “butterfly structures.”

The first Pool Section 930A transitions to a second Pool Section 930B and therein to a third Pool Section 930C. Each of the first Pool Section 930A, second Pool Section 930B, and third Pool Section 930C being formed within the MMOB 900. The lengths of these sections of the pool being d₁, d₂, and d₃ respectively. An Edge-Coupled Semiconductor Device (EC-SD) 990 mounted upon a CoC 980 which is positioned to abut the end of the third Pool Section 930C. Accordingly, the EC-SD 990 and CoC 980 form a fourth wall of the pool whereas the sidewalls of the first Pool Section 930A, second Pool Section 930B, and third Pool Section 930C form another pair of sidewalls of the pool whilst the end of the Optical Fiber 950 forms the final sidewall of the pool within which the liquid(s) are disposed for the formation of the PPS Core 960 and/or PPS cladding.

The PPS provides an optical “bridge” between the Optical Fiber 950 and the emitting or absorbing region (optical facet) of the facet of the EC-SD 990 which transitions from a first mode field diameter (MFD) of the Optical Fiber 950 to a second MFD of the optical facet of the EC-SD 990. The dimensions of the first Pool Section 930A, second Pool Section 930B, and third Pool Section 930C are established in dependence upon several factors, including the dimensions of the two optical elements being interconnected, providing a clear field of view for the optical imaging system used to acquire the locations for the ends of the PPS, and providing clear access for the illumination system employed to form the PPS core and/or cladding. The dimensions may also depend upon whether one or both ends are coupling to angled interfaces etc. In other embodiments of the invention these aspects may be modified if the MMOB 900 allows optical imaging system and the illumination system to access different sides of the MMOB 900.

Where the optical imaging system and illumination system are optically based then the MMOB 900 must be transparent or have low attenuation in the applicable wavelength range(s). However, in other instances with non-optical illumination for forming the PPS this requirement may be modified such that the MMOB 900 is transparent or has low attenuation for the non-optical illumination system for forming the PPS whereas the optical imaging system does not view through the MMOB 900.

Within FIG. 9 the dimensions of second Pool Section 930B are smaller, at least laterally, than the first Pool Section 930A and second Pool Section 930C as the optical imaging system does not require access to these regions. Once the locations of the ends of the PPS are defined then the path of the PPS is defined by a processing system that then controls the illumination system forming the PPS and/or a positioning system upon which the CoC 980 and MMOB 900 are mounted via a sub-carrier, package, etc. Accordingly, within other embodiments of the invention the pool may comprise a single section, two sections, four sections or more. Further, the lateral width and depth of each section may vary rather than being constant.

### D1C: Laser Cavity

The depth of another (third) set of cavities is engineered such that the laser waveguide core is co-axial and/or co-planar with the core of the optical fiber on one end and with a silicon nitride waveguide core on the other end. It is determined considering the thickness of the laser die, that of the mounting material(s) (e.g., adhesive(s), or micro-bumps for soldering or thermocompression bonding) holding the laser die in place, and the required clearance for the PPS tool's optical column objective to have sufficient room to operate that these cavities are deeper. Further, the lateral size of the cavity is engineered to minimize the escape volume of PPS material as it spills out from the second set of pools while leaving enough space for gripping effectors of a pick-and-place machine, for example, to maneuver the laser die into position within the cavity. Whilst a design may be established that aligns the optical cores the manufacturing tolerances and assembly tolerances of each element lead to deviations from this nominal aligned situation. Accordingly, the PPS enables these tolerances and offsets to be accommodated with an improved performance and/or yield of the final product.

Depending on the architecture of the laser diode (e.g., metal on top or on both sides), then a suitable electrode material may be deposited and patterned at the bottom of the cavity or on the sidewalls to provide an electrical contact. The architecture of the laser cavity may further include a recess with sufficient space to allow standard electrical wire bonding between pads/tracks on the substrate the cavity is formed within and the laser die. Accordingly, this recess should provide sufficient access for the bonding tool, e.g., a thermo-sonic bonding tool tip.

### D1D: Second Set of Pools

The second set of receptacle cavities, or pools, receive and contain the first material(s) from which the PPS is formed, such as liquid photoresist for example. This may be solely from consideration of the PPS core when the PPS is air-clad or without consideration of one or more second materials providing the PPS cladding as this is simply disposed within the cavity and may extend above and outside the cavity in some embodiments of the invention without issue. In other embodiments of the invention these receptacle cavities (pools, either first set of pools and/or second set of pools) may be designed to limit the flow and/or volume of the one or more second materials employed to form the PPS cladding. Additional UV or thermally cured adhesive or polymer-based containment structures may also be patterned prior to the PPS process around the cavity so as to limit the leakage of uncured/unexposed PPS materials.

Each PPS core is directly written into the first material(s) between the facet of the laser die forming or associated with what is referred to as the “back” or “rear” mirror (i.e. the mirror on the opposite end of the laser diode disposed towards the “front” mirror which is disposed between the gain region of the laser diode and the optical fiber which connects the laser diode to the optical network) and the silicon nitride waveguide core coupling the emitted optical signals from the laser diode to the optical spectrometer stage.

The size of this second set of pools is again established to provide for line-of-sight visual access to the cores of the silicon nitride waveguide and the waveguide on the “rear” facet of the laser diode (which is coupled to the rear mirror waveguide of the laser diode) so that the vision system of the PPS writing tool can locate these features, lock onto them and write the PPS core. The size of the second set of pools is also adapted in dependence upon the viscosity of the first material(s) (e.g. photoresist) and the capillarity forces arising of these first material(s) in conjunction with the different elements and their gaps, dimensions etc. to provide repeatable, sufficient, yet minimal volume of these first material(s) to be dispensed and maintained in location to ensure a repeatable PPS writing process. The side of the second set of pools facing the laser diode die is open ended in a similar manner to the first set of pools. The design of this second set of pools allows for easy removal of the photoresist at the develop stage.

### D2: Printed Photonic Structure Waveguides

A benefit of printed photonic structure technology is that the waveguide design can adapted to different mode field diameters (MFDs) commensurate with the waveguide technology it is being coupled with, their MFDs, the wavelength(s) of interest, etc. provided that the MFD for the waveguides being interconnected is known and characterized. In this manner the PPS can be designed and implemented to couple between two waveguides where the MFD of the PPS varies from one end to the other for low coupling loss to either waveguide at either end.

Accordingly, a PPS can optically connect waveguides and/or devices of differing MFDs through engineering of the PPS core diameter and its variation along the propagation axis. Within embodiments of the invention the inventors establish design regimes for the length and shape of the PPS allowing sufficient mode field diameter conversion distance and minimize adiabatic optical losses whilst maintaining low propagation losses and minimal thermo-chemical shrink tension. Although the waveguide cores are co-planar, as designed without considering manufacturing tolerances, the PPS may be designed with a geometry tolerant and robust to differential thermal displacements incurred by the heterogeneous multi-material integration scheme. Further, the PPS cladding material(s) in addition to covering the PPS core and the mating interfaces to fibers and lasers can be employed to provide intrinsic passivation and encapsulation of the optical coupling link, providing for tolerance to variable ambient conditions.

### D3: Laser Co-Integrated With WLL Silicon Photonics Chip on Common Second Carrier

According to an embodiment of the invention a wavelength locker block consists of a discrete silicon photonics chip with its spectrometric demultiplexing filter and the optical-to-electrical conversion sections. Accordingly, within an embodiment of the invention the integration of the WLL with the laser diode employs four additional elements:
1) A third section is added to the standalone WLL block to achieve the optical connectivity to the laser diode,
2) A custom metallized laser carrier (e.g., a ceramic carrier) is designed to accommodate the WLL block;
3) An underlying common carrier is employed; and
4) An optical input/output (I/O) block implemented to connect the laser to the exterior network.

### D3A: WLL Block With Optical I/O Section to the Laser Diode

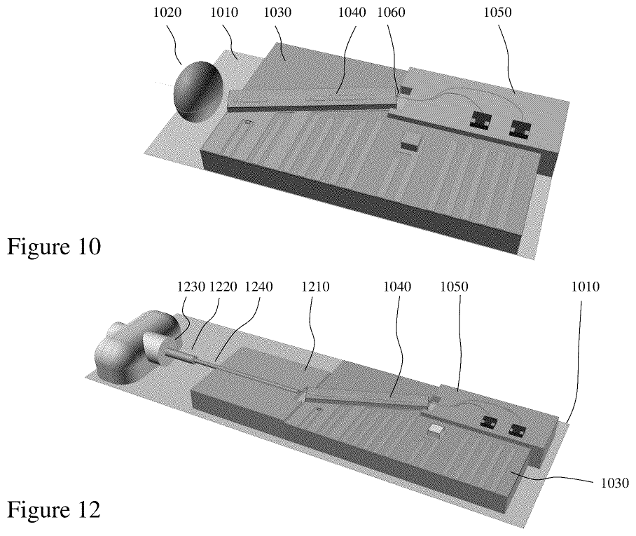

Within an embodiment of the invention (see for example FIGS. 10 and 12), which expands upon prior work by the inventors with respect to an optical fiber block (fiber block) for facilitating optical interconnection between a laser diode and optical fiber, the WLL block comprises an additional custom-sized open-ended cavity on the side of the WLL block facing the laser diode. This “receptacle,” once adjoined to and pushed against the laser diode chip-on-carrier (CoC) defines a pool intended to receive and contain the material(s) from which the PPS core is written. The dimensions of this pool are engineered to accommodate the laser chip mounting such that either the facet of the laser diode overhangs at an angle or it is parallel to the axis of the pool allowing for line-of-sight visual access to the cores of the silicon nitride waveguide from the WLL and the laser waveguide so that the vision system of the PPS writing tool can locate and lock onto them. The size of the pool may also be engineered to adapt to a laser diode that would be flush mounted on its carrier without any overhang. In all cases, the size of the pool also allows for repeatable, sufficient, yet minimal volume of photoresist to be dispensed and maintained in location to ensure a repeatable PPS writing process. The pool design allows for easy removal of the photoresist at the develop stage.

### D3B: Custom Metallized Laser Diode Carrier

A first carrier onto which a laser diode die (chip) or PIC is integrated is a thermally conductive substrate (for example providing thermal conductivity of 18 W/m.K or more) with a suitable coefficient of thermal expansion (CTE) to the laser diode die or PIC for reliable long-term operation under varying temperature. This carrier would also have appropriate surface metallization patterns to allow laser die mounting (bonding) and local electrical interconnection (e.g., gold (Au) wire bonding) to the laser diode electrical contents for biasing in the event of CW operation of the laser diode and biassing/modulation in the event of direct modulation of the laser diode output.

Within an embodiment of the invention, the carrier may be a ceramic (e.g., alumina (Al203), aluminum nitride (AlN), or silicon carbide (SiC)), a metal alloy or a metal composite substrate. The carrier may be flat or equipped with machined/stamped/defined standoffs and comprises a recess, or an enclave suitably sized to welcome and accommodate the WLL block. The laser can be mounted such that the emitting edge is coincident with the carrier edge (flush mount) facing the WLL block, slightly backed off, or overhanging whereby the emitting edge extends beyond the carrier edge facing the WLL block by a distance, for example 0 μm and 100 μm.

Semiconductor laser chips being often designed with an intentional miscut of a few degrees to mitigate interfacial reflections, the laser can also be mounted at a corresponding angle on the carrier with a variable amount of overhang (or recess) on the carrier. In fact, the PPS technology renders the integration scheme agnostic of the presence of an angled facet. hence allowing for flexible laser chip implementation choices or retrofittable integrations. The thickness of the carrier is engineered to make the laser waveguide co-planar, and in some instances co-axial, with the silicon nitride core from the WLL block considering the thickness of the adhesives used to attach the laser carrier chip and the WLL block on the common carrier.

The semiconductor laser chip or PIC is attached to its carrier in such a way that topographic features used for optical detection are facing the PPS writing tool vision system. Therefore, the laser is bonded with its p-side up in case of lasers grown on a n-type substrate. In case of a flip chip laser with coplanar contacts (lasers grown on semi-insulating substrates or n-type substrate), the laser is bonded with its co-planar n and p contacts up, with topographic features visible to the PPS writing tool. The laser chip-on-carrier components (such as thermistors, termination capacitors and resistors, and internal wirebonds loops) are selected and assembled such as they do not violate the maximum height above the lowest point between the laser waveguide output and the fiber core center, to prevent interference with the PPS writing tool.

### D3C: Common Carrier

The common, or second, carrier provides support for both the laser carrier and the WLL block. This may similarly consist of a thermally conductive substrate (e.g., >18 W/m.K) with suitable CTE to limit the thermo-mechanical stress on the PPS between the laser diode and the WLL block. This carrier may be a ceramic (e.g., alumina, aluminum nitride, or silicon carbide), a metal alloy or a metal composite substrate. In some instances, this carrier may be the upper portion of a thermo-electric controller (TEC), these typically formed from a ceramic such as alumina. The support carrier may be large enough to receive the laser carrier, the WLL block, any other standoffs or electrical I/O blocks for internal or external electrical interconnect, and any optical I/O block connecting the laser to the outer world in flush mount, overhanging or recessed schemes.

Referring to FIG. 10 there is depicted a schematic of a Common Carrier 1010 upon which both a WLL 1050, for example a PIC, is disposed together with a Laser Carrier 1030. Mount atop the Laser Carrier 1030 is a Laser Die 1040. Depicted between the WLL 1050 and Laser Die 1040 is PPS 1060 (representing the core of the PPS). The other facet of the Laser Die 1040 is coupled to Free Space Optics 1020, e.g., a ball lens, graded refractive index lens etc. which couples the output of the Laser Die 1040 to an optical fiber with within the package comprising the Common Carrier 1010 and its associated elements or externally via an expanded beam optical interface.

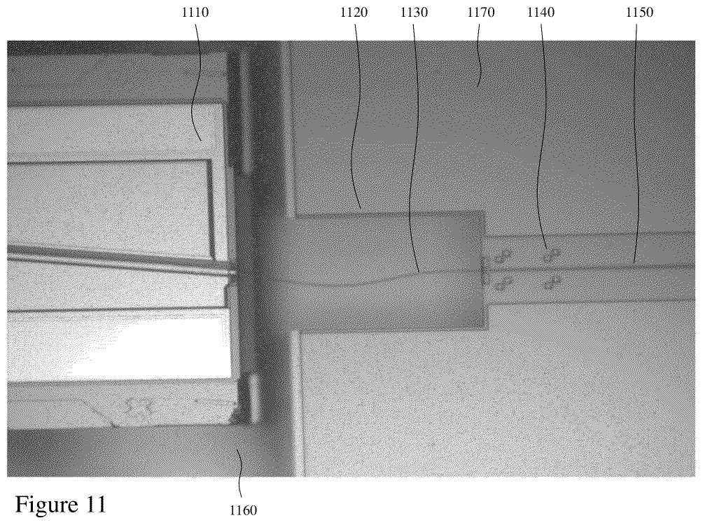

Referring to FIG. 11 there is depicted a photograph of an exemplary PPS interconnect as described and depicted in FIG. 10 by PPS 1060. Accordingly, there is depicted:
Laser Die 1110 (e.g., Laser Die 1040 in FIG. 10);
Pool 1120, i.e., a recess defined in the end of the WLL die which has the final which becomes a pool due to the fourth “wall” being provided by a Laser Carrier 1160 and Laser Die 1110;
PPS Core 1130;
Optical Fiduciary Markers 1140 on WLL die 1170 adjacent to the PIC waveguide being coupled to;
WLL Waveguide 1150; and
Laser Carrier 1160.

### D3D: Optical I/O Block

An optical I/O block with optical fiber may connect the laser to the network as depicted in FIG. 12 rather than free-space interconnect or free-space coupling to an optical fiber. Within FIG. 12 there is depicted a schematic of a chip-on-carrier (CoC) optical emitter with a micro-machined optical bench (MMOB) retaining an optical fiber upon a common carrier as supported by embodiments of the invention. Accordingly, there is depicted the Laser Carrier 1030 with Laser Die 1040 atop a Common Carrier 1010 in a similar configuration as depicted in FIG. 10. In this instance the WLL has been omitted. Disposed adjacent to the left of the Laser Carrier 1030 and also mounted to the Common Carrier 1010 is MMOB 1210 with Optical Fiber 1240. The Optical Fiber 1240 is the core-cladding of diameter 125 μm or 80 μm for example. The Optical Fiber 1240 transitions to first Region 1220 where the Optical Fiber 1240 is clad with a primary coating, e.g., an acrylate, before transitioning to second Region 1230 wherein the outer body of the cable within which the Optical Fiber 1240 is disposed is depicted. Accordingly, rather than a free-space optical coupling from the Laser Die 1040 to the Optical Fiber 1240 a PPS would be implemented between the end facet of the Optical Fiber 1240 and the end facet of the Laser Die 1040 such as depicted in FIG. 10 for example.

The micro-machined optical bench (MMOB) 1210 is designed to receive the optical fiber and the optical/structural adhesives for attachment. It may, for example, be fabricated from a 200 mm silicon-on-insulator (SOI) wafer whereby the total thickness and the thickness of the top silicon slab are engineered to make the optical fiber cores co-planar and co-axial with the laser waveguide to which they are matched. These thicknesses are engineered considering that of the adhesive used to attach the laser carrier chip and of the MMOB on the common carrier. The lateral dimensions of the fiber block are optimized to allow compact common lateral co-packaging together with the laser chip-on-carrier on a common carrier. The U-grooves are etched into the top silicon slab using any suitable anisotropic patterning process, such as Deep Reactive Ion Etching (DRIE) for instance, with the Buried Oxide (BOX) acting as an etch-stop guaranteeing repeatable etch depths for a fiber mechanical stop. The U-grooves have lengths, widths and depths engineered to tightly receive and host stripped ends of optical fibers. They were adapted to standard 125 μm fiber diameter and reduced fiber diameters such as 80 μm. They can also be engineered to introduce a controlled vertical offset of a few tens of μm to improve yield repeatability and efficiency. This design leaves enough space for the controlled dispense and capillary-force driven infiltration of structural (and/or optical) UV (and/or thermally) curable adhesives. The controlled dispense is engineered for maximum infiltration coverage to provide for both thermo-mechanical stability of the fiber in the U-Groove and an optimal index contrast to enhance the fiber core detection by the vision system of the printed photonic structure writing tool. The U-Grooves lengths are also engineered to set a repeatable distance in the light propagation axis (x) between the optical fiber cores and the opposing laser waveguide cores.

The micro-machined optical bench (MMOB) also comprise a first custom-sized open-ended receptacle (pool), located between the optical fiber and the opposing laser chips-on-carriers. These receptacles, once adjoined to and pushed against the laser chip-on carriers define pools are meant to receive and contain the liquid photoresist in which the printed photonic structure cores are to be written. The size of the pools is engineered to welcome and accommodate laser chips overhanging at an angle or straight from their carrier while allowing for line-of-sight visual access to the cores of the optical fiber and laser waveguides so that the vision system of the PPS writing tool can locate and lock onto them. The size of the pools also allows for repeatable, sufficient, yet minimal volume of photoresist to be dispensed and maintained in location to ensure a repeatable PPS writing process. The pool design allows for easy removal of the photoresist at the develop stage.

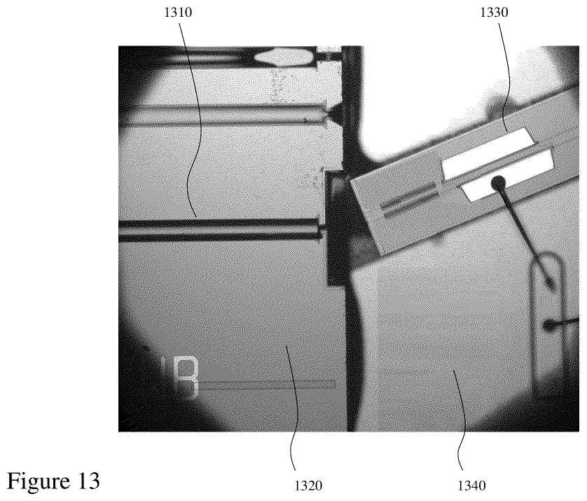

Referring to FIG. 13 there is depicted an optical photograph of an assembled optical emitter—optical fiber assembly as depicted schematically in FIG. 12. The Optical Fiber 1310, MMOB 1320, Laser Die 1330 and Laser Carrier 1340 being evident within the optical photograph.

Optionally, the micro-machined optical bench (MMOB) comprises a second closed receptacle or pool (referred to by the inventors as an integrated pool or sub-pool) may be located along the MMOB inside the MMOB chip itself. This integrated pool/sub-pool provides improved access to an adhesive dispense needle which dispenses the controlled quantity of structural/optical adhesive into the integrated pool. Then, due to geometry of the U-groove, optical fiber and viscosity of the adhesive, the adhesive is “wicked” along the length of the U-groove by capillary action. Once the optical or structural adhesives are cured, the pool can later receive strain relief adhesive to further strengthen the assembly.

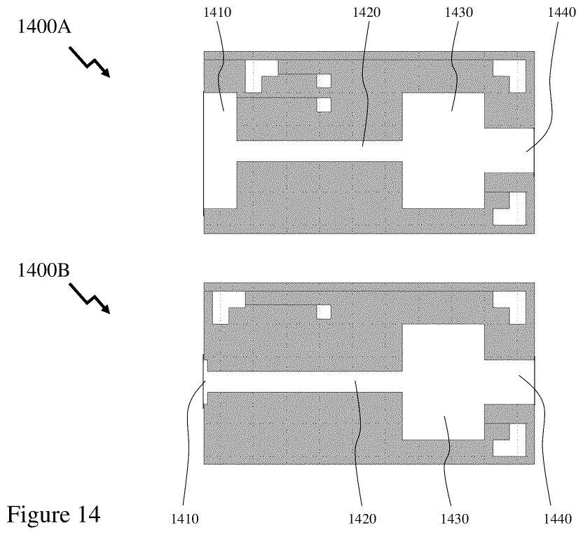

Now referring to FIG. 14 there are plan view schematics of two designs of micro-machined optical bench (MMOB) for retaining an optical fiber according to embodiments of the invention. First Schematic 1400A depicts a MMOB with U-groove 1420, pool 1410 for abutting to a CoC, the integrated pool (or sub-pool as described above) 1430 within which the adhesive to retain the optical fiber is disposed and second U-groove 1440 which is dimensioned to support the primary coating of the optical fiber. Second Schematic 1400B depicts the same structure with a smaller pool 1410 for use, for example, when the remainder of the pool forms part of a CoC.

### D4: Laser Co-Integrated With Two-Tier Metallized Ceramic Carrier With WLL Silicon Photonics Chip

Within this embodiment of the invention, the wavelength locker block consists of a standalone photonics integrated circuit with its spectrometric demultiplexing filter and the optical-to-electrical conversion sections. The embodiment is then comprised of two additional elements:
1) A third section is added to the standalone WLL block to achieve the optical connectivity to the laser; and
2) A custom metallized laser carrier designed to accommodate the WLL block in a co-packaging scheme.

Within this embodiment of the invention the WLL block employs an optical coupling section to the laser diode die. The WLL block (i.e., the PIC chip) includes an additional custom-sized open-ended cavity on the side facing the laser. This receptacle, once adjoined to and pushed against the laser chip-on-carrier defines a pool intended to receive and contain the material(s) (e.g., liquid photoresist) utilized in forming the PPS core. The size of the pool is engineered to welcome and accommodate laser chips overhanging at an angle or straight from their carrier while allowing for line-of-sight visual access to the cores of the silicon nitride waveguide from the WLL and the laser waveguide so that the vision system of the PPS writing tool can locate and lock onto them. The size of the pool could also be engineered to be adapted to a laser that would be flush mounted on its carrier. In all cases, the size of the pool also allows for repeatable, sufficient, yet minimal volume of photoresist to be dispensed and maintained in location to ensure a repeatable PPS writing process. The pool design allows for easy removal of the photoresist at the develop stage.

Within this embodiment of the invention a custom geometry metallized carrier is employed upon which the laser chip or laser chip and PIC are assembled. The carrier is typically formed from a thermally conductive substrate (>18 W/m.K) with suitable CTE for reliable operation, and appropriate surface metallization patterns to allow electrical connection to the laser die (and the PIC if assembled onto this carrier for any tuning elements within the optical spectrometer stage but at least for the electrical connections to the one or more MPDs employed by the PIC. As discussed above such a carrier may be a ceramic, a metal alloy, or a metal composite substrate.

Within this embodiment the carrier comprises a pair of tiers. The first of which is flat or equipped with machined standoffs. The second tier lies lower by an amount engineered to accept and accommodate the WLL block.

The laser diode may be mounted such that the emitting edge is coincident with the carrier edge (flush mount) facing the WLL block, slightly backed off, or overhanging whereby the emitting edge extends beyond the carrier edge facing the WLL block by a distance between 0 μm and 100 μm, for example. Semiconductor laser chips being often designed with an intentional angled facet of a few degrees to mitigate interfacial reflections, the laser can also be mounted at a corresponding angle on the carrier with a variable amount of overhang (or recess) on the carrier. In fact, the PPS technology renders the integration scheme agnostic of the presence of an angled facet, hence allowing for flexible laser chip implementation choices or retrofittable integrations (see for example FIG. 11). The height difference between the two tiers is engineered to make the laser waveguide co-planar—and in some instances co-axial—with the silicon nitride core from the WLL block considering the thickness of the adhesives used to attach the laser carrier chip and the WLL block on the carrier surface.

The semiconductor laser chip or PIC is attached to its carrier in such a way that topographic features used for optical detection are facing the PPS writing tool vision system. Therefore, the laser is bonded with its p-side up in case of lasers grown on a n-type substrate. In case of a flip chip laser with coplanar contacts (lasers grown on semi-insulating substrates or n-type substrate), the laser is bonded with its co-planar n and p contacts up, with topographic features visible to the PPS writing tool. The laser chip-on-carrier components (such as thermistors, termination capacitors and resistors, and internal wirebonds loops) are selected and assembled such as they do not violate the maximum height above the lowest point between the laser waveguide output and the fiber core center, to prevent interference with the PPS writing tool.

Optionally, the two-tier carrier may be formed from High Temperature Co-Fired Ceramic (HTCC) using layer ceramic green tapes which are stamped/punched etc. and co-fired. Beneficially, this approach allows high thermal conductivity alumina, silicon carbide or aluminum nitride to be employed with metallization etc. Alternatively, the two-tier carrier may be formed by machining a carrier at the final thickness to form the step within it.

### E: Printed Photonic Structures for Guided and Unguided Optical Interconnections Between Optical Components

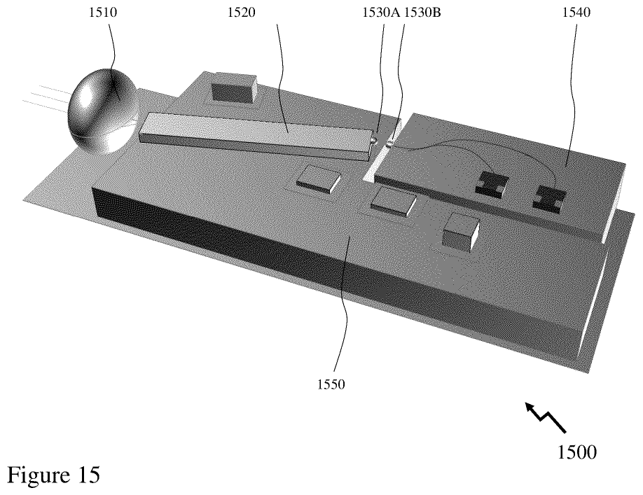

Referring to FIG. 15 there is depicted a schematics of assembly 1500 of hybrid integration of a III-V laser diode to a wavelength locker (WLL) PIC die with PPS micro-lenses on the laser diode back facet and the WLL PIC input facet with a free-space interface to the network according to an embodiment of the invention.

Assembly 1500 depicts hybrid integration of a III-V laser diode to a wavelength locker (WLL) PIC die with a PPS on the laser diode back facet and another PPS on the WLL PIC input facet with free-space coupling to the network fiber according to an embodiment of the invention. Assembly 1500 comprising a III-V laser diode (LD) 1520 which is coupled to the external network via a first PPS Micro-Lens 1510 which may be a spherical lens, aspherical lens, GRIN lens or other lens either manufactured by one or more PPS processes in-situ. Assembly 1500 also comprising a Carrier 1550 upon which the LD 1520 is mounted and a WLL Die 1540 coupled the back facet of the LD 1520 via second and third PPS Micro-Lenses 1530A and 1530B. Optionally, first PPS Micro-Lens 1510 may be a non-PPS micro-lens.

Assembly 1500 and its method of assembly support integration of LD 1520 and WLL 1540 with PPS Micro-Lens 1510 in different embodiments including, but not limited to, three classes as defined by the inventors. These being:
L1: the laser diode is co-integrated on the same silicon photonics chip as implementing the WLL block;
L2: the laser diode is integrated on its own metallized carrier, which is then co-packaged with the WLL (for example, a silicon chip assembly or a PIC chip assembly); and
L3: the laser diode is integrated on its own two-tier metallized carrier.

A common feature between embodiments is the employment of facet-attached optical micro-lenses installed by printed photonic structure manufacturing techniques on both the laser diode rear facet and the WLL die. To minimize external back reflections to the laser diode, the laser diode and WLL facets are treated for low reflectivity by using angled waveguides or angled facets and/or anti-reflection coatings matched to the index of refraction of the PPS micro-lenses.

The laser back facet lenses, second and third PPS Micro-Lenses 1530A and 1530B, are designed and written such that a collimated beam exists between the second PPS Micro-lens 1530A printed onto the laser diode facet and the third PPS Micro-Lens 1530B printed onto the WLL input facet. The lens system formed by the second and third PPS Micro-Lenses 1530A and 1530B is designed and written to image the supported optical mode at the laser facet onto the supported optical mode at the WLL input facet. A vision assisted detection system is employed to locate alignment features and reference surfaces associated to both laser waveguide facet and WLL waveguide facet.

With respect to the different classes of embodiments then these may require one or more of the following features:
A laser diode die with specific facet height with respect to die attach reference surface.
A laser carrier with a specific thickness and specific shape (L2).
A laser carrier with a specific thickness, a die attach reference surface at specific height, and a specific shape (L3).
A WLL die with a specific height and shape (L2, L3).

With respect to the different classes of embodiments then using one or more additive manufacturing techniques to print PPS structures then the second and third PPS Micro-Lenses 1530A and 1530B are printed onto the laser back facet and WLL input facet respectively. The printing step(s) may be performed at wafer level packaging, die level packaging or module level packaging.

With respect to the different classes of embodiments then the WLL die comprises an optical circuit formed by an optical waveguide to provide the wavelength filtering reference which terminates on the facet of the WLL die. Within embodiments of the invention the WLL die comprises an optical circuit that may employ, for example, a silicon nitride/silica waveguide, a silicon/silicon-on-insulator rib waveguide, or metal diffused waveguides as well as other waveguides employed in forming planar lightwave circuits (PLCs).

With respect to the different classes of embodiments then WLL die comprises an additional facet or surface grating to couple tap and wavelength filtering circuits to MPDs. These MPDs may, for example, be hybrid integrated using, for example, shallow or deep pockets or they may be monolithically integrated into the WLL die. The WLL die may comprise metallic trace to route electrical signals.

With respect to the different classes of embodiments then WLL die may comprise a pocket structure, under and/or around the waveguide(s) on the input facet for receiving a micro-lens, to contain dispensed resins of the 3D additive printing process (not depicted in FIG. 15, but analogous to those employed within other embodiments of the invention such as the MMOB for example, and to maintain a proper distance between the 2 facets.

The integration methodology depicted in FIG. 15 using printed micro-lenses allows for printed photonic structures where in some wavelength ranges, such as for example printing with visible light, a micro lens integration scheme may be more practical than a guided PPS integration due to additive manufacturing resolution limitations of one or more printing steps employed in forming the PPS elements.

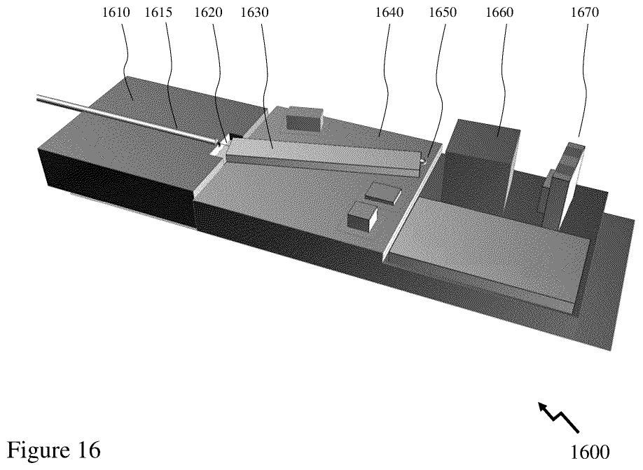

Now referring to FIG. 16 there is depicted a schematic of an Assembly 1600 of hybrid integration of a III-V laser diode to a WLL micro-optical assembly with PPS elements to provide free space interconnect of the WLL to the laser diode according to an embodiment of the invention.

Assembly 1600 depicts a MMOB 1610 and Optical Fiber 1615 where the Optical Fiber 1615 is coupled to a Laser Diode (LD) 1630 mounted upon a Carrier 1640 via a Guided PPS 1620. The LD 1630 is coupled to a free space wavelength locker implementation via a Micro-Lens PPS 1650. The free space wavelength locker implementation comprises a free-space solid etalon 1660 and MPD 1670. The MPD 1670 collects light filtered by the free space solid etalon 1660. Where optical power monitoring is within the LD 1630 then no additional MPD is required but where on-chip power measurement is not integrated within the LD 1630 then a beam splitter and a second MPD could be implemented as part of free-space wavelength locker for reference power monitoring purposes.

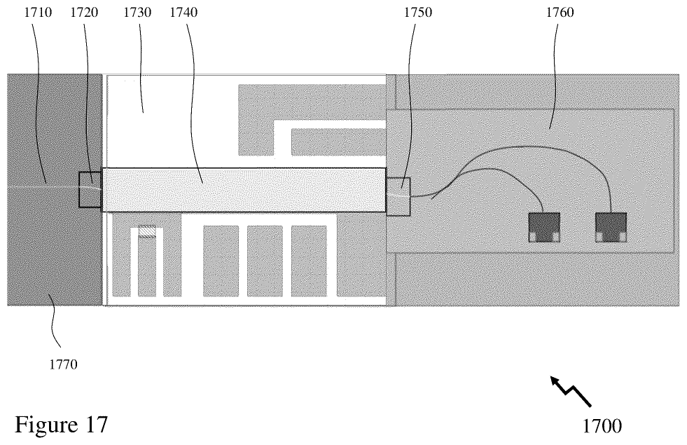

Referring to FIG. 17 depicts a schematic of an Assembly 1700 for hybrid integration of a III-V laser diode to a WLL die using PPS elements between the laser back facet and the WLL input facet and the laser front facet and a SiN waveguide according to an embodiment of the invention. Assembly 1700 comprises a PIC 1770 with a Waveguide 1710 which is coupled to a first facet of a LD 1740 upon a Carrier 1730 via a first Guided PPS 1720. A second distal facet of the LD 1740 us coupled to a WLL PIC 1760 via second Guided PPS 1750.

Within the embodiment depicted the optical waveguide(s) on the LD 1740 are angled with respect to the facets of the LD 1740. The first and second Guided PPS 1720 and 1750 respectively adapt/accommodate the direction of the light emission by printing the appropriate core structures. In this manner, the LD 1740 may be mounted “straight” enabling compact packaging and “pools” with low complexity for the PPS printing process(es).

Optionally, the PIC 1770, Carrier 1730, and WLL PIC 1760 may be three discrete substrates whilst within other embodiments of the invention two or more of the PIC 1770, Carrier 1730, and WLL PIC 1760 may be formed on a common substrate.

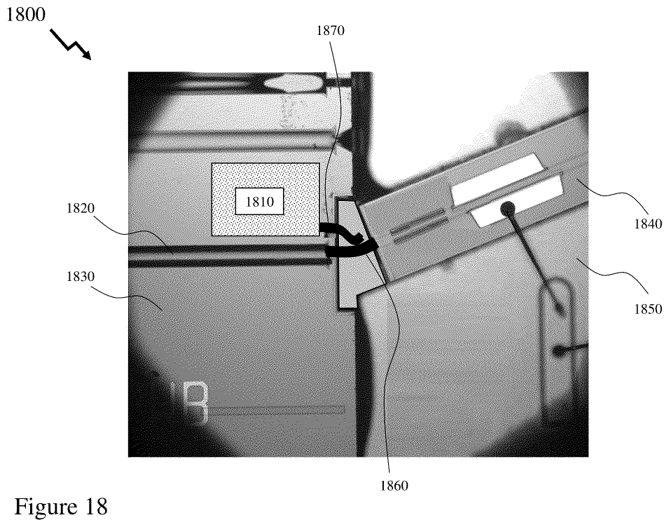

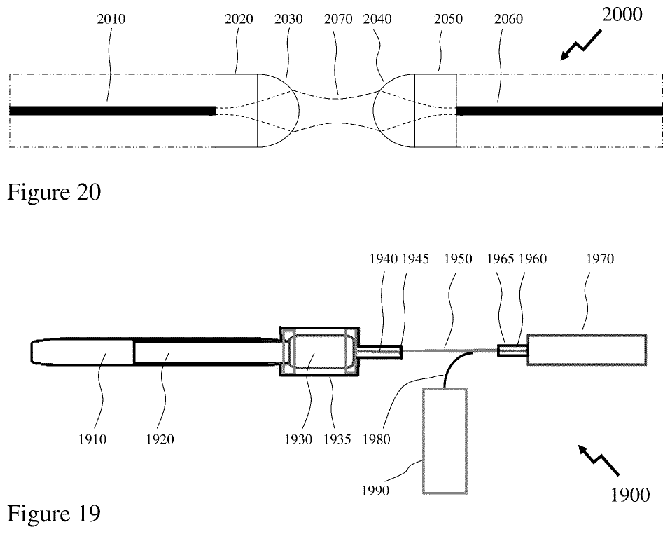

Now referring to FIGS. 18 and 19 there are depicted schematics of Assemblies 1800 and 1900 for edge emitter hybrid packaging to a WLL front facet power tap integrated within the PPS interconnecting the edge emitter to an optical fiber according to an embodiment of the invention. Referring initially to Assembly 1800 there is depicted a laser diode (LD) die 1840 mounted upon a Carrier 1850. Disposed to the left of the LD 1840 is an MMOB 1830 within which is disposed an Optical Fiber 1820 such as described above with respect to other embodiments of the invention. Disposed upon the MMOB 1830 or integrated within the MMOB 1830 is WLL Circuit 1810. The Optical Fiber 1820 being coupled to the optical waveguide of LD 1840 via first Guided PPS 1860. The WLL Circuit 1810 being coupled to the first Guided PPS 1860 via second Guided PPS 1870. Second Guided PPS 1870 providing a power tap from first Guided PPS 1860.

Accordingly, the embodiment of the invention depicted in FIG. 18 implements a photonic circuit comprising:
a photonic component such as laser diode, semiconductor optical amplifier, waveguide photodetector with a waveguide and an exposed edge facet forming a wall of or over hanging a wall of a cavity, recess or pocket within which a Guided PPS, such as a photonic wire bond for example, will be printed;
a mechanical holder for an optical fiber, e.g. a U-Groove or V-Groove;
the cavity, recess or pocket of specific size, depth and shape between the facet of the optical fiber and the photonic component;
a photonic integrated circuit formed within or upon the mechanical holder of the optical fiber;
a Guided PPS to couple between the optical fiber facet and the waveguide of the photonic component; and
another Guided PPS forming a power tap from the Guided PPS to the wavelength locker.

Optionally, within other embodiments of the invention the optical fiber may be an optical waveguide formed within the “mechanical holder.” Optionally, this optical waveguide and the photonic integrated circuit may be integrated within the “mechanical holder”, i.e. carrier or substrate.

The tap ratio of the power tap formed by the Guided PPS and the another Guided PPS and/or the wavelength characteristics of the power tap may be designed according to the requirements of the assembled photonic component. The cores of the Guided PPS and the another Guided PPS may be written in one printing step or multiple printing steps concurrently or discretely. Optionally, the Guided PPS may be written and the photonic component performance monitored as the another Guided PPS is printed from the photonic integrated circuit to the Guided PPS and the power tap formed. Where the photonic component is an optical emitter the photonic integrated circuit may provide WLL and/or MPD functionality.

The Assembly 1900 in FIG. 19 within an alternate embodiment of the invention implements the same functionality as Assembly 1800 in FIG. 18. As depicted an Optical Fiber 1910 is assembled into a Groove 1920 of a carrier (not depicted for clarity). The Optical Fiber 1910 being coupled to an Isolator 1930 disposed within a first cavity 1935 within the carrier, this may for example be by direct coupling, a micro-lens formed on the end of the Optical Fiber 1910 such as a non-Guided PPS, a lens formed by melting the tip of the Optical Fiber 1910, or via a Guided PPS.

The other end of the Isolator 1920 is coupled to a first end of a first Waveguide 1950 formed within or upon the carrier via a first Guided PPS 1940 formed within a second Cavity 1945 within the carrier. The second distal end of the first Waveguide 1950 is coupled to LD 1970 via a second Guided PPS 1960 formed within a third Cavity 1965. Optionally, the LD 1970 may itself be disposed within the carrier within another cavity or be part of the carrier. A WLL 1990 is coupled to the first Waveguide 1950 via second Waveguide 1980 which forms a tap coupler with the first Waveguide 1950. In a similar manner to the LD 1970 the WLL 1990 may itself be disposed within the carrier within another cavity or be part of the carrier.

Optionally, within an embodiment of the invention first Waveguide 1950 and second Waveguide 1980 may also be guided PPS elements printed in the same printing step or a different printing step to one or both of the first Guided PPS 1940 and second Guided PPS 1960.

The Isolator 1920 may be based upon a Faraday rotator such as described with U.S. Patent Provisional Patent Application 63/363,730 entitled “Hybrid Integration Methods, Devices, and Systems exploiting Active-Passive Photonic Elements” and the World Intellectual Property Organization patent application claiming priority from it.

Referring to FIG. 20 there is depicted a free-space optical interconnection methodology employing PPS elements in Schematic 2000. As depicted a first Waveguide 2010 is coupled to a second Waveguide 2060 via a Free-Space Beam 2070. Disposed on the end of the first Waveguide 2010 is a first Spacer 2020 and then a first Unguided PPS. Similarly, disposed on the second Waveguide 2060 are second Spacer 2050 and second Unguided PPS 2040. Accordingly, the optical signals from first Waveguide 2010 diverge within the first Spacer 2020 before being “collimated” by the first Unguided PPS 2030 wherein these are then coupled to the second Unguided PPS 2040 and converge through the second Spacer 2050 onto the second Waveguide 2060.

Once, the first Waveguide 2010 and second Waveguide 2060 are positioned relative to one another, with their respective spacers, the PPS printing system can print the first Unguided PPS 2030 and second Unguided PPS 2040. Based upon the printing system determining the positions of the ends of the first Waveguide 2010 and the second Waveguide 2060 the passive alignment can be compensated for through the design of the first and second Unguided PPSs 2030 and 2040 respectively.

Based upon the printing system determining the positions of the ends of the first Waveguide 2010 and the second Waveguide 2060 and the characteristics of the first Waveguide 2010 and second Waveguide 2060 the thicknesses of the first Spacer 2020 and second Spacer 2050 may be defined together with the designs of the first and second Unguided PPSs 2030 and 2040 respectively. Optionally, one or both of the first Spacer 2020 and second Spacer 2050 may also be printed into the same material as the first and second Unguided PPSs 2030 and 2040 respectively or a different material. Optionally, the materials for the first and second Unguided PPSs 2030 and 2040 respectively may be same or different or each be a combination of materials. The first Spacer 2020 and second Spacer 2050 may, optionally, be printed before the first and second Unguided PPSs 2030 and 2040 respectively.

Optionally, according to the design space of the first and second Unguided PPSs 2030 and 2040 and the characteristics of the first Waveguide 2010 and second Waveguide 2060 one or both of the first Spacer 2020 and second Spacer 2050 may not be required.

Within embodiments of the invention where the Free Space Beam 2070 is within air, vacuum, low pressure environment or an inert atmosphere (e.g. nitrogen), the external surfaces of the first and second Unguided PPSs 2030 and 2040 may be coated to reduce Fresnel reflections etc. Within embodiments of the invention each of the first and second Waveguides 2010 and 2060 may be selected from the group comprising an optical fiber, a passive waveguide within a PIC, an active waveguide within a PIC and a waveguide within a material. Within other embodiments of the invention the region between the first and second Unguided PPSs 2030 and 2040 respectively may be printed from a material of defined characteristics where this region is factored into the design of the first and second Unguided PPSs 2030 and 2040 respectively.

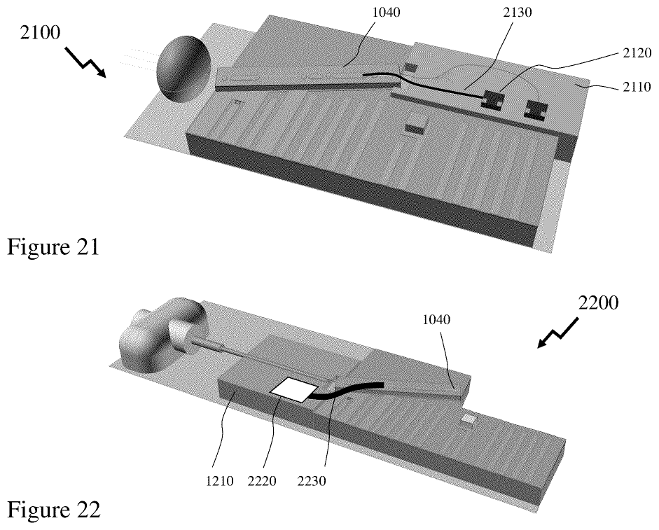

Now referring to FIGS. 21 and 22 there are depicted schematics of optical Assemblies 2100 and 2200 exploiting PPS elements to couple optical signals between elements wherein a portion of each PPS element is upon an upper surface of an optical element, performing evanescent coupling, rather than disposed on a facet of the optical element. Referring initially to Assembly 2100 in FIG. 21 then this is a similar design concept as that described with respect to FIG. 10. Within FIG. 10 the WLL 1050 is depicted simply with a MPD and the filtering element(s) not shown for clarity. Within Assembly 2100 in FIG. 21 the WLL 2110 now comprises an additional MPD 2120. MPD 2120 is optically connected to the LD 1040 via Guided PPS 2130 which is printed from a location on top of the LD 1040 to the MPD 2120. The Guided PPS 2130 being evanescently coupled to a waveguide within the LD 1040 at a first end and connected to the MPD 2120 at a second distal end. This may be similarly by evanescent coupling, butt coupling to an active layer of the MPD 2120 at an edge of the MPD 2120 or coupled via a 90° mirror, for example, at the second distal end of the Guided PPS 2130.

Within other embodiments of the invention Guided PPS elements may be written from a first end coupled to a PIC, LD, SOA etc. to a second end coupling to a waveguide or optical elements upon another die in order to bypass a defect in the optical waveguide of the PIC, LD, SOA etc. that would otherwise have been coupled to the optical element directly or via a Guided PPS upon the facet of the PIC, LD, SOA etc. Optionally, the Guided PPS 2130 may be coupled to a facet of a waveguide within the PIC, LD, SOA etc., for example LD 1040, which is not at an edge of the die.

Optionally, a Guided PPS may be written to couple from one location upon a PIC, LD, SOA to another location on the PIC, LD, SOA to similarly bypass a defective region of a waveguide allowing an otherwise defective die to be used.

Now referring to Assembly 2200 in FIG. 22 then this is a similar design concept as that described with respect to FIG. 12 except that the WLL coupled to the rear facet of the LD 1040 has now been replaced by a WLL 2220 integrated within or assembled upon the MMOB 1210 which is coupled to the front facet of the LD by Guided PPS 2230 which is printed from a location on top of the LD 1040 to the WLL 2220. The Guided PPS 2230 being evanescently coupled to a waveguide within the LD 1040 at a first end and connected to the WLL 2220 at a second distal end. This may be similarly by evanescent coupling, butt coupling to a waveguide at a facet of the WLLL 2220 or coupled via a 90° mirror, for example, at the second distal end of the Guided PPS 2230.

Within an embodiment of the invention the Guided PPS 2230 may be coupled via a 90° mirror to a surface grating that couples to a waveguide of the WLL 2230 where according to the desired wavelength of the LD 1040 the second distal end of the Guided PPS 2230 is printed at a predetermined surface grating of a series of surface grating defined within the WLL 2220. Optionally, the Guided PPS 2230 may be coupled to a facet of a waveguide within the PIC, LD, SOA etc., for example LD 1040, which is not at an edge of the die.

A Guided PPS may include, but not be limited to, what is known in the art as a photonic wire bond (wirebond). An Unguided PPS may include, but not be limited to, a lens or micro-lens.

It would be evident to one of skill in the art that the design process and/or design space for the PPS is linked to the SiN process flow as this enables the taper design through lithography/etch process and in terms of decreasing losses by control of the waveguide stack thickness which relates through to the use of specific SOI wafers and processes.

Within the embodiments of the invention described supra in respect of embodiments of the invention optical waveguides exploiting a silicon nitride core with silicon oxide upper and lower cladding, a SiO₂-Si₃N₄-SiO₂ waveguide structure has been described and depicted together with a silicon core and silicon nitride upper and lower claddings, a waveguide structure. However, it would be evident that other waveguide structures may be employed including, but not limited to, silica-on-silicon, with doped (e.g., germanium, Ge) silica core relative to undoped cladding, silicon oxynitride, polymer-on-silicon, doped silicon waveguides. Additionally, other waveguide structures may be employed including vertical and/or lateral waveguide tapers and forming microball lenses on the ends of the waveguides via laser and/or arc melting of the waveguide tip. Further, embodiments of the invention have been described primarily with respect to the optical alignment of silicon-on-insulator (SOI) waveguides, e.g. SiO₂-Si₃N₄-SiO₂; SiO₂-Ge: SiO₂-SiO₂; or Si—SiO₂, but it would be evident embodiments of the invention may be employed to coupled passive waveguides to active semiconductor waveguides, such as indium phosphide (InP) or gallium arsenide (GaAs), e.g. a semiconductor optical amplifier (SOA), laser diode, etc. Optionally, an active semiconductor structure may be epitaxially grown onto a silicon IO-MEMS structure, epitaxially lifted off from a wafer and bonded to a silicon IO-MEMS structure, etc. However, it would be evident to one skilled in the art that the embodiments of the invention may be employed in a variety of waveguide coupling structures coupling onto and/or from waveguides employing material systems that include, but not limited to, SiO₂-Si₃N₄-SiO₂; SiO₂-Ge: SiO₂-SiO₂; Si—SiO₂; ion exchanged glass, ion implanted glass, polymeric waveguides, InGaAsP, GaAs, III-V materials, II-VI materials, SiGe, and optical fiber. Whilst primarily waveguide-waveguide systems have been described it would be evident to one skilled in the art that embodiments of the invention may be employed in aligning intermediate coupling optics, e.g., ball lenses, spherical lenses, aspherical lenses, graded refractive index (GRIN) lenses, etc. for free-space coupling into and/or from a waveguide device.

Values of design parameters, material parameters, performance parameters, processing parameters etc. within the specification relate to initial experiments, devices, etc. undertaken by the inventors. The scope of the invention is not defined by these as other values of design parameters, material parameters, performance parameters, processing parameters etc. may be employed without departing from the scope of the invention.

Specific details are given in the above description to provide a thorough understanding of the embodiments. However, it is understood that the embodiments may be practiced without these specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

The foregoing disclosure of the exemplary embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed is:

1. A method comprising:
providing a semiconductor laser diode (SLD) comprising:
an optical waveguide between a first end of the SLD and a second distal end of the SLD;
providing a photonic integrated circuit (PIC) comprising:
an input waveguide to be optically coupled to the second distal end of the SLD for receiving optical signals generated by the SLD;
an optical spectrometer circuit having an input coupled to the input waveguide and a plurality of output waveguides; and
a plurality of monitoring photodiodes (MPDs), each MPD of the plurality of MPDs coupled to a predetermined output waveguide of the plurality of output waveguides;
providing an optical fiber having a facet to be optically coupled to the first end of the SLD for receiving optical signals generated by the SLD;
assembling the SLD upon a first carrier;
assembling the PIC upon a second carrier;
assembling the optical fiber upon a micro-machined optical bench (MMOB);
forming a first printed photonic structure (PPS) disposed between the optical fiber and the optical waveguide of the SLD at the first end of the SLD; and
forming a second PPS disposed between the input waveguide of the PIC and the optical waveguide of the SLD at the second distal end of the SLD.

2. The method according to claim 1, wherein
the first PPS is a photonic wire bond; and
the second PPS is another photonic wire bond.

3. The method according to claim 1, wherein
the first PPS is formed by direct writing a waveguide core of the first PPS within one or more materials disposed within a first pool;
a first sidewall of the first pool is formed within the MMOB;
a second sidewall of the first pool is formed within the MMOB opposite the first sidewall;
a first portion of a third sidewall of the first pool is formed within the MMOB and extends between the first sidewall and the second sidewall proximate the end of the optical fiber;
a second portion of the third sidewall is formed by the facet of the optical fiber;
a first portion of a fourth sidewall of the first pool is formed by the first carrier; and
a second portion of the fourth sidewall is formed by the first end of the SLD.

4. The method according to claim 1, wherein
the second PPS is formed by direct writing a waveguide core of the second PPS within one or more materials disposed within a second pool;
a first sidewall of the second pool is formed within the PIC;
a second sidewall of the second pool is formed within the PIC opposite the first sidewall;
a third sidewall of the second pool is formed within PIC and extends between the first sidewall and the second sidewall proximate the end of the input waveguide of the PIC;
a first portion of a fourth sidewall of the second pool is formed by the first carrier; and
a second portion of the fourth sidewall is formed by the second distal end of the SLD.

5. The method according to claim 1, wherein
the first carrier is mounted to the second carrier;
the thickness of the first carrier is established in dependence upon the thickness of the PIC, the thickness of the input waveguide and the thickness of the SLD; and
a height of an optical mode emitted from the second distal end of the optical waveguide of the SLD from the second carrier is established such that in the absence of manufacturing tolerances it is aligned with a height of another optical mode where the another optical mode is that of the input waveguide.

6. The method according to claim 1, wherein
the MMOB is mounted to the second carrier;
the optical fiber is mounted within a groove formed within the MMOB;
the thickness of the MMOB carrier and the depth of the groove are established in dependence upon an outer diameter of the optical fiber, a thickness of the first carrier, and a thickness of the SLD; and
a height of an optical mode emitted from the first end of the optical waveguide of the SLD from the second carrier is established such that in the absence of manufacturing offsets it is equal to a height of another optical mode where the another optical mode is that of the optical fiber.

7. The method according to claim 1, wherein
the MMOB is mounted to the second carrier;
the optical fiber is mounted within a groove formed within the MMOB wherein the groove is formed by etching through a silicon layer of the second carrier to a buried oxide etch stop;
the thickness of the MMOB second carrier and the depth of the groove are established in dependence upon an outer diameter of the optical fiber, a thickness of the first carrier, and a thickness of the SLD; and
a height of an optical mode emitted from the first end of the optical waveguide of the SLD from the second carrier is established such that in the absence of manufacturing offsets it is equal to a height of another optical mode from the second carrier where the another optical mode is that of the optical fiber.

8. The method according to claim 1, wherein
each MPD comprises a semiconductor stack atop a third carrier;
each MPD of the plurality of MPDs is inserted within a cavity formed within the PIC;
the cavity is formed by etching through a waveguide stack of the PIC atop a silicon layer and the silicon layer to a buried oxide (BOX) etch stop within the PIC;
the thickness of third carrier is established in dependence upon the semiconductor stack, the waveguide stack and the silicon layer such that in the absence of manufacturing offsets the height of an intrinsic layer within the semiconductor stack within the MPD from the BOX is equal to the height of an optical mode of the plurality of output waveguides from the BOX.

9. The method according to claim 1, wherein
the SLD further comprises:
a first distributed Bragg mirror disposed within the optical waveguide towards a first end of the SLD; and
a second distributed Bragg mirror disposed within the optical waveguide at a second distal end of the SLD.

10. A method comprising:
providing a semiconductor laser diode (SLD) comprising:
an optical waveguide between a first end of the SLD and a second distal end of the SLD;
providing a photonic integrated circuit (PIC) comprising:
an input waveguide to be optically coupled to the second distal end of the SLD for receiving optical signals generated by the SLD;
an optical filter having an input coupled to the input waveguide and an output; and
a monitoring photodiode (MPD) coupled to the output of the optical filter;
assembling the SLD upon a first carrier;
assembling the PIC upon a second carrier;
positioning the second carrier in a position relative to the first carrier such that second distal end of the optical waveguide of the SLD and the input waveguide of the PIC are disposed facing each other;
forming a first printed photonic structure (PPS) upon the second distal end of the optical waveguide of the SLD; and
forming a second PPS upon a facet of the PIC at the input waveguide; wherein
the first PPS and second PPS are printed in situ once the second carrier and first carrier have been positioned.

11. The method according to claim 10, wherein
the first PPS is a micro-lens; and
the second PPS is another micro-lens.

12. The method according to claim 10, further comprising
providing an optical fiber having a facet coupled to the first end of the SLD for receiving optical signals generated by the SLD;
assembling the optical fiber upon a micro-machined optical bench (MMOB);
positioning the MMOB in a position relative to the first carrier such that the facet of the optical fiber and the first end of the optical waveguide are disposed facing each other; and
forming a third PPS having a first end coupled to a core of the optical fiber at the facet of the optical fiber and a second distal end coupled to the optical waveguide at the first end of the SLD.

13. The method according to claim 10, further comprising
forming a third PPS upon either the first carrier or another carrier to which the first carrier is mounted; wherein
the third PPS is a lense which couples optical signals from the optical waveguide at the first end of the SLD.

14. A method comprising:
providing an optical waveguide forming part of an optical circuit;
providing an optical element to be optically coupled to the optical waveguide;
assembling the optical circuit and optical element as part of an optical component;
forming a printed photonic structure (PPS) to optically couple signals from the optical waveguide to a predetermined portion of the optical element.

15. The method according to claim 14, wherein
the predetermined portion of the optical element is a photodiode;
the PPS is evanescently coupled to the optical waveguide at a first end; and
the PPS is one of evanescently coupled, butt-coupled or coupled via a 90° mirror to the predetermined portion of the optical element.

16. The method according to claim 14, wherein
the predetermined portion of the optical element is another waveguide;
the PPS is evanescently coupled to the optical waveguide at a first end; and
the PPS is one of evanescently coupled and butt-coupled to the predetermined portion of the optical element.

17. The method according to claim 14, wherein
the predetermined portion of the optical element is a surface grating;
the PPS is evanescently coupled to the optical waveguide at a first end; and
the PPS is coupled via a 90° mirror to the predetermined portion of the optical element.

18. A method comprising:
providing an optical waveguide forming part of an optical circuit;
providing an optical element to be optically coupled to the optical waveguide;
providing another optical element;
assembling the optical circuit and optical elements? as part of an optical component;
forming a first printed photonic structure (PPS) to couple optical signals from the optical waveguide to a predetermined portion of the optical element;
forming a second PPS to couple a portion of the optical signals from the first PPS to a predetermined portion of the another optical element.
